(19) United States
(12) Patent Application Publication
(10) Pub. No.: US 2026/0143678 A1
(43) Pub. Date: May 21, 2026

(54) SEMICONDUCTOR DEVICES

(71) Applicant: Samsung Electronics Co., Ltd., Suwon-si (KR)

(72) Inventors: Kihyung Sim, Suwon-si (KR); Hyungki Cho, Suwon-si (KR); Kyeongju Moon, Suwon-si (KR); Gunjoo Woo, Suwon-si (KR); Minji Hong, Suwon-si (KR)

(21) Appl. No.: 19/381,200

(22) Filed: Nov. 6, 2025

(30) Foreign Application Priority Data
Nov. 15, 2024 (KR) 10-2024-0163369

(51) Int. Cl. H10B 12/00; H10B 80/00; H10W 80/00; H10W 90/00; H10W 90/20

(52) U.S. Cl. CPC H10B 12/315; H10B 12/05; H10B 80/00; H10W 80/312; H10W 90/20; H10W 90/792

(57) ABSTRACT

A semiconductor device includes a mold line extending in a first horizontal direction, an active semiconductor layer on a sidewall of the mold line and including a first oxide semiconductor, a word line extending along a first sidewall of the active semiconductor layer in the first horizontal direction, a cell capacitor on a top surface of the active semiconductor layer, a bit line on a bottom surface of the active semiconductor layer opposite the top surface and extending in a second horizontal direction, and an encapsulation line extending in the second horizontal direction between the bottom surface of the active semiconductor layer and the bit line. The encapsulation line includes a first metal, where the first metal comprises at least one of tantalum, niobium, or aluminum.

### CROSS-REFERENCE TO RELATED APPLICATION

This application is based on and claims priority under 35 U.S.C. § 119 to Korean Patent Application No. 10-2024-0163369, filed on Nov. 15, 2024, in the Korean Intellectual Property Office, the disclosure of which is incorporated by reference herein in its entirety.

### FIELD

The inventive concept relates to a semiconductor device, and more particularly, to a semiconductor device including a vertical channel transistor.

### BACKGROUND

As semiconductor devices are downscaled, dynamic random-access memory (DRAM) devices become smaller. In DRAM devices with a 1T-1C structure (in which one capacitor is connected to one transistor) become smaller, leakage current through the channel area therein may increase. To reduce leakage current, a vertical channel transistor using an oxide semiconductor material as a channel layer has been proposed.

### SUMMARY

The inventive concept provides a semiconductor device with improved electronic performance.

According to an aspect of the inventive concept, there is provided a semiconductor device including a mold line extending in a first horizontal direction, an active semiconductor layer on a sidewall of the mold line and including a first oxide semiconductor, a word line on a first sidewall of the active semiconductor layer and extending in the first horizontal direction, a cell capacitor on a top surface of the active semiconductor layer, a bit line on a bottom surface of the active semiconductor layer opposite the top surface and extending in a second horizontal direction that intersects the first horizontal direction, and an encapsulation line extending in the second horizontal direction between the bottom surface of the active semiconductor layer and the bit line, the encapsulation line including a first metal, wherein the first metal includes at least one of tantalum, niobium, or aluminum.

According to another aspect of the inventive concept, there is provided a semiconductor device including a mold line extending in a first horizontal direction, an active semiconductor layer on a sidewall of the mold line and including a first oxide semiconductor, a word line extending along a first sidewall of the active semiconductor layer in the first horizontal direction, a cell capacitor on a top surface of the active semiconductor layer, a bit line on a bottom surface of the active semiconductor layer opposite the top surface and extending in a second horizontal direction that intersects the first horizontal direction, and an encapsulation line extending in the second horizontal direction between the bottom surface of the active semiconductor layer and the bit line, the encapsulation line including a first metal including at least one of tantalum, niobium, or aluminum, wherein a portion of the encapsulation line is in contact with the bottom surface of the active semiconductor layer, and the portion of the encapsulation line includes an oxide region including at least one of tantalum oxide, niobium oxide, or aluminum oxide.

According to another aspect of the inventive concept, there is provided a semiconductor device including a peripheral circuit area and a cell array area on the peripheral circuit area, wherein the cell array area includes a mold line extending in a first horizontal direction, an active semiconductor layer on a sidewall of the mold line and including a first oxide semiconductor, a word line extending along a first sidewall of the active semiconductor layer in the first horizontal direction, a cell capacitor on a top surface of the active semiconductor layer, a bit line on a bottom surface of the active semiconductor layer opposite the top surface and extending in a second horizontal direction that intersects the first horizontal direction, and an encapsulation line extending in the second horizontal direction between the bottom surface of the active semiconductor layer and the bit line, the encapsulation line including a first metal including at least one of tantalum, niobium, or aluminum.

### BRIEF DESCRIPTION OF THE DRAWINGS

Embodiments will be more clearly understood from the following detailed description taken in conjunction with the accompanying drawings in which:

FIG. 1 is a schematic diagram of a semiconductor device according to some embodiments;

FIG. 2 is an enlarged layout view of a cell array area in FIG. 1;

FIG. 3 is a cross-sectional view taken along line A1-A1′ in FIG. 2;

FIG. 4 is a cross-sectional view taken along line A2-A2′ in FIG. 2;

FIG. 5 is an enlarged view of portion CX1 in FIG. 3;

FIG. 6 is an enlarged view of portion CX2 in FIG. 4;

FIGS. 7 and 8 are cross-sectional views of a semiconductor device according to some embodiments;

FIG. 9 is an enlarged view of portion CX1 in FIG. 7;

FIG. 10 is an enlarged view of portion CX2 in FIG. 8; and

FIGS. 11A to 26 are schematic diagrams illustrating a method of manufacturing the semiconductor device, according to some embodiments. Specifically, FIG. 11A, FIG. 12A, FIG. 13, FIG. 14, FIG. 15A, FIG. 16A, FIG. 17A, FIG. 18A, FIG. 19, FIG. 20A, FIG. 21A, FIG. 22A, FIG. 23A, and FIGS. 24, 25, and 26 are cross-sectional views taken along line A1-A1′ in FIG. 2; FIG. 15B, FIG. 16B, FIG. 17B, FIG. 18B, FIG. 20B, FIG. 21B, FIG. 22B, and FIG. 23B are cross-sectional views taken along line A2-A2′ in FIG. 2; FIG. 11B, FIG. 12B, and FIG. 22C are plan views corresponding to the cross-sectional views of FIGS. 11A, 12A, and 22A, respectively; and FIG. 21C is an enlarged view of portion CX1 in FIG. 21A.

### DETAILED DESCRIPTION OF EMBODIMENTS

The terms “first,” “second,” etc., may be used herein merely to distinguish one component, layer, direction, etc. from another. The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” may be used herein to refer to a physical and/or electrical connection. When components or layers are referred to herein as “directly” on, or “in direct contact” or “directly connected,” no intervening components or layers are present.

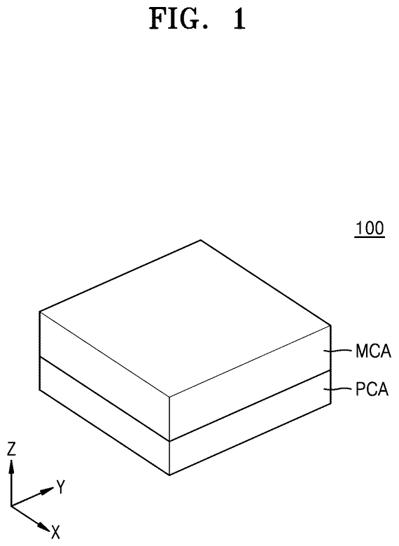

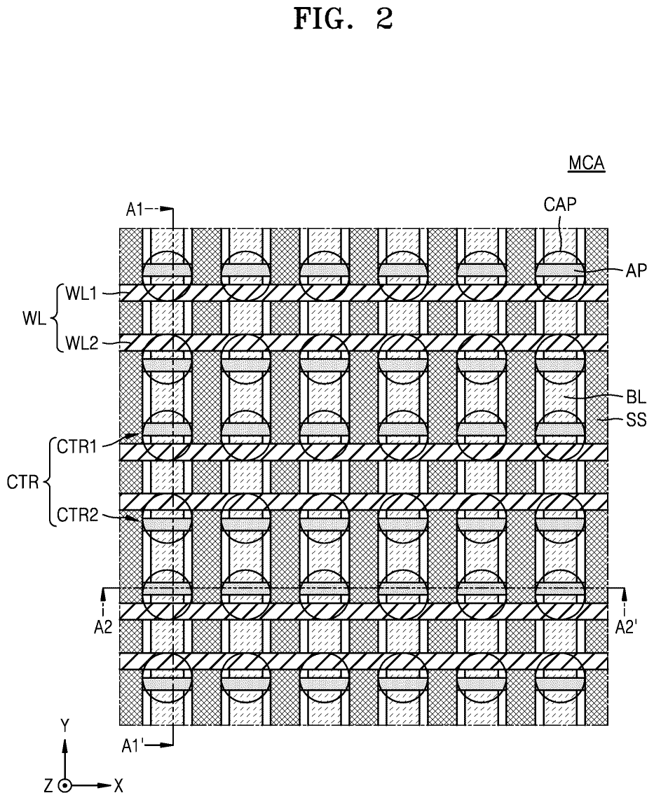

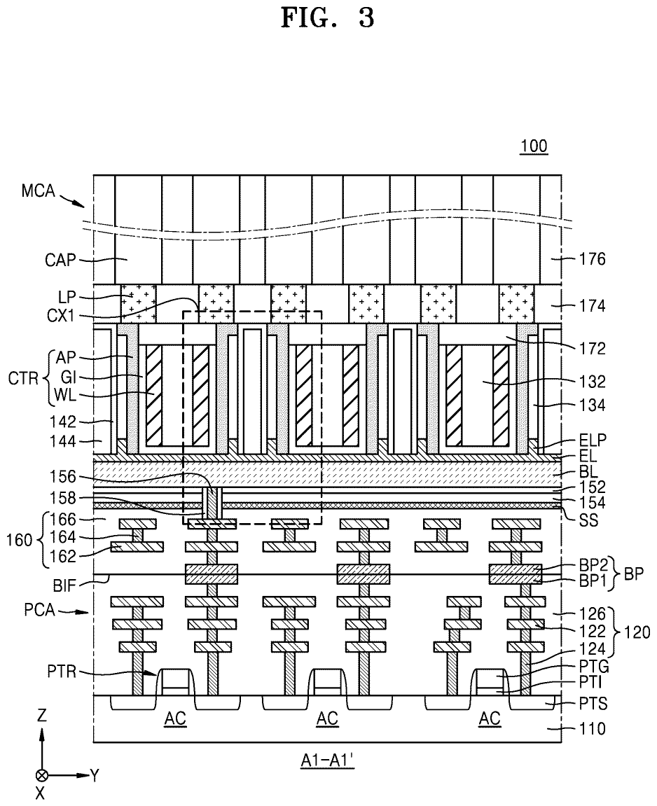

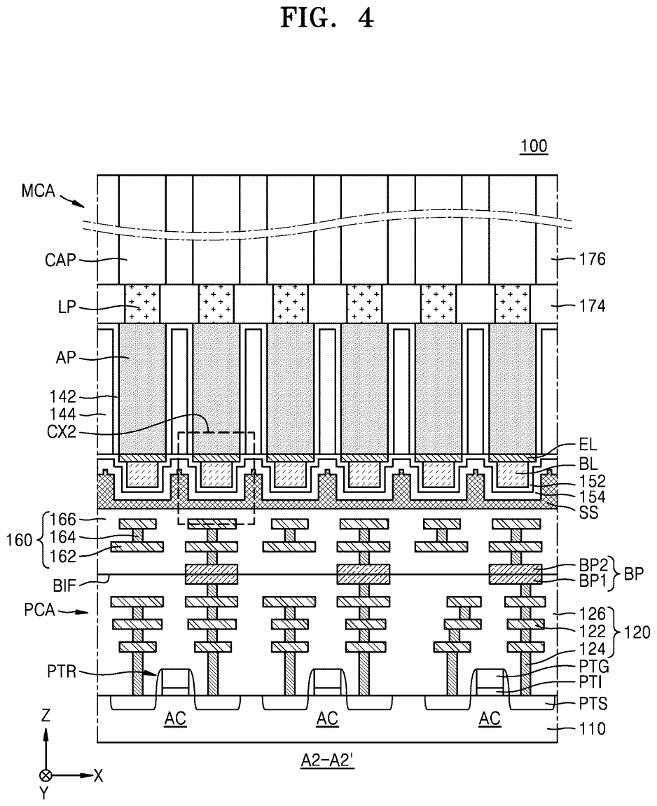

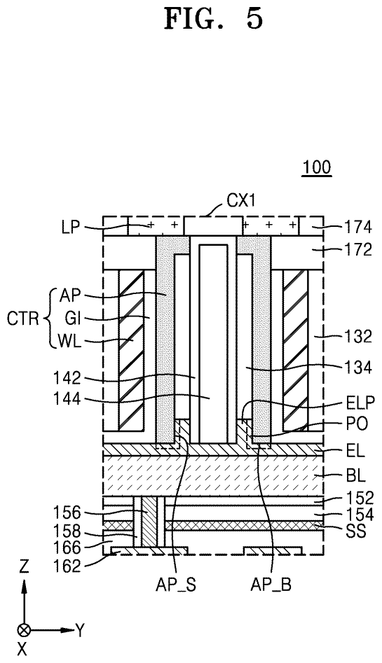

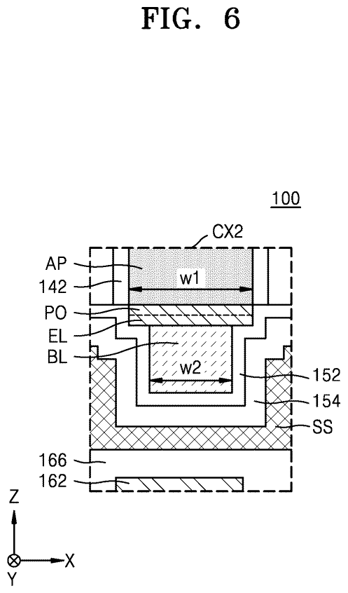

FIG. 1 is a schematic diagram of a semiconductor device 100 according to some embodiments. FIG. 2 is an enlarged layout view of a cell array area MCA in FIG. 1. FIG. 3 is a cross-sectional view taken along line A1-A1′ in FIG. 2. FIG. 4 is a cross-sectional view taken along line A2-A2′ in FIG. 2. FIG. 5 is an enlarged view of portion CX1 in FIG. 3. FIG. 6 is an enlarged view of portion CX2 in FIG. 4.

Referring to FIGS. 1 to 6, the semiconductor device 100 may include a peripheral circuit area PCA and a cell array area MCA arranged at a higher vertical level than the peripheral circuit area PCA. A “level” (e.g., a vertical level) as described herein may refer to a distance (e.g., a vertical distance) of a particular element or layer from a reference element or layer, e.g., a substrate 110 or bit line BL described herein. Horizontal direction(s) (e.g., X- or Y-) may extend parallel to a surface of a reference element or layer (such as the substrate 110), while vertical directions (e.g., Z-) may extend perpendicular to the reference element or layer.

In some embodiments, the cell array area MCA may include a memory cell area of a dynamic random-access memory (DRAM) device, and the peripheral circuit area PCA may include a core area or a peripheral circuit area of the DRAM device. For example, the peripheral circuit area PCA may include a peripheral circuit transistor PTR for transmitting signals and/or power supply to a memory cell array included in the cell array area MCA. In some embodiments, the peripheral circuit transistor PTR may constitute various circuits, such as a command decoder, control logic, an address buffer, a row decoder, a column decoder, a sense amplifier, and a data input/output circuit.

As shown in FIG. 2, a plurality of word lines WL extending in a first horizontal direction X and a plurality of bit lines BL extending in a second horizontal direction Y may be arranged in the cell array area MCA. A plurality of cell transistors CTR may be arranged at intersections of the plurality of word lines WL and the plurality of bit lines BL. A plurality of cell capacitors CAP may be disposed on the plurality of cell transistors CTR, respectively.

The plurality of word lines WL may include a first word line WL1 and a second word line WL2 alternately arranged in the second horizontal direction Y. The plurality of cell transistors CTR may include a first cell transistor CTR1 and a second cell transistor CTR2 alternately arranged in the second horizontal direction Y. The first cell transistor CTR1 may be arranged adjacent to the first word line WL1 and the second cell transistor CTR2 may be arranged adjacent to the second word line WL2. The first cell transistor CTR1 and the second cell transistor CTR2 may have a mirror-symmetric structure. For example, the first cell transistor CTR1 and the second cell transistor CTR2 may have a mirror-symmetric structure (also referred to as mirror symmetry) with respect to a center line between the first cell transistor CTR1 and the second cell transistor CTR2, each extending in the first horizontal direction X.

In some embodiments, a pitch of the plurality of bit lines BL (e.g., a sum of a width of one bit line BL and an interval between two adjacent bit lines BL) may be 2F. A pitch of the first word line WL1 may be 2F or a pitch of the second word line WL2 may be 2F. A unit area for forming one cell transistor CTR may be 4F². Therefore, the cell transistor CTR may have a cross-point type which requires a relatively small unit area. Thus, this may be advantageous to improve the integration of the semiconductor device 100.

Although not shown, an edge region may be arranged around the cell array area MCA. The edge region may include a region in which an electrical connection member for the word line WL and/or an electrical connection member for the bit line BL are arranged. The edge region may also include a region in which an electrical connection member providing electrical connection between the cell array area MCA and the peripheral circuit area PCA is arranged.

Described below is a case where the cell array area MCA is arranged at a higher vertical level than the peripheral circuit area PCA (e.g., a case where the cell array area MCA is disposed on the peripheral circuit area PCA), as illustrated with reference to FIGS. 3 and 4. However, the semiconductor device 100 may be arranged upside down such that the cell array area MCA is located at a lower vertical level than the peripheral circuit area PCA. In this case, a “top surface” or a “bottom surface” of components in the following description should be understood as referring to the “bottom surface” or “top surface” of the components, respectively. The components described as being located “above” or “below” a component should be understood as being located “below” or “above” the component, respectively. The components described as being “arranged at a higher vertical level” should be understood as being “arranged at a lower vertical level”. That is, spatially relative terms such as “top,” “bottom,” “above,” “upper,” “upper portion,” “upper surface,” “below,” “lower,” “lower portion,” “lower surface,” “side surface,” and the like may refer to the figures, but are intended to encompass different orientations of the device in use or operation in addition to the orientation depicted in the figures. For example, if the device in the figures is turned over, elements described as “below” or “beneath” other elements or features would then be oriented “above” the other elements or features.

The substrate 110 may include silicon, for example, single crystal silicon, polycrystalline silicon, or amorphous silicon. In other embodiments, the substrate 110 may include at least one selected from germanium (Ge), silicon-germanium (SiGe), silicon carbide (SiC), gallium arsenide (GaAs), indium arsenide (InAs), and indium phosphide (InP). In some embodiments, the substrate 110 may include a conductive region, e.g., an impurity-doped well, or an impurity-doped structure.

In the peripheral circuit area PCA, an active region AC may be defined in the substrate 110 and a peripheral circuit transistor PTR may be disposed on the active region AC of the substrate 110. The peripheral circuit transistor PTR may include a gate electrode PTG, a gate insulating layer PTI, and a source/drain region PTS.

A peripheral circuit wiring structure 120 of the peripheral circuit transistor PTR may be disposed on the substrate 110. The peripheral circuit wiring structure 120 may include a peripheral circuit wiring 122, a peripheral circuit contact 124, and a peripheral circuit insulating layer 126. The peripheral circuit wiring 122 and the peripheral circuit contact 124 may be electrically connected to the peripheral circuit transistor PTR and/or the substrate 110, and the peripheral circuit insulating layer 126 may cover the peripheral circuit transistor PTR, the peripheral circuit wiring 122, and the peripheral circuit contact 124, on the substrate 110. The term “cover” or “surround” or “fill” as may be used herein may not require completely covering or surrounding or filling the described elements or layers, but may, for example, refer to partially covering or surrounding or filling the described elements or layers, for example, with voids, spaces, or other discontinuities therein. The peripheral circuit insulating layer 126 may include an oxide film, a nitride film, a low-k dielectric film, or a combination thereof and may be formed as a laminated structure of multiple insulating layers.

The peripheral circuit area PCA may be bonded to the cell array area MCA. In some embodiments, the boundary between the peripheral circuit area PCA and the cell array area MCA may be referred to as a bonding interface BIF. For example, a portion of the semiconductor device 100 arranged at a lower vertical level than the bonding interface BIF shown in FIG. 3 may be referred to as the peripheral circuit area PCA, and a portion of the semiconductor device 100 arranged at a higher vertical level than the bonding interface BIF may be referred to the cell array area MCA.

In some embodiments, the peripheral circuit wiring structure 120 may contact the cell wiring structure 160 with the bonding interface BIF therebetween. The cell wiring structure 160 may include a cell wiring layer 162, a cell via 164, and a cell insulating layer 166.

A bonding pad BP may be arranged at an interface (e.g., the bonding interface BIF) between the cell wiring structure 160 and the peripheral circuit wiring structure 120. The bonding pad BP may include a first bonding pad BP1 and a second bonding pad BP2. A top surface of the first bonding pad BP1 may be arranged at the same level as a top surface of the peripheral circuit insulating layer 126, a bottom surface of the second bonding pad BP2 may be arranged at the same level as a bottom surface of the cell insulating layer 166, and the top surface of the first bonding pad BP1 may be in contact with the bottom surface of the second bonding pad BP2.

In some embodiments, the cell wiring structure 160 and the peripheral circuit wiring structure 120 may be bonded to each other by a metal-oxide hybrid bonding method. In this case, an interface between the peripheral circuit insulating layer 126 and the cell insulating layer 166 may be arranged at the same plane as an interface between the first bonding pad BP1 and the second bonding pad BP2 (e.g., the interface between the peripheral circuit insulating layer 126 and the cell insulating layer 166 and the interface between the first bonding pad BP1 and the second bonding pad BP2 may be coplanar and arranged along the bonding interface BIF).

In other embodiments, the cell wiring structure 160 and the peripheral circuit wiring structure 120 may be bonded to each other by an oxide bonding method. In this case, the bonding pad BP may be omitted.

The plurality of bit lines BL may be disposed on the cell wiring structure 160. The cell transistor CTR may be disposed on the plurality of bit lines BL. A cell capacitor CAP may be disposed on the cell transistor CTR. In some embodiments, the bit line BL may be arranged closer to the bonding interface BIF than the cell transistor CTR or the cell capacitor CAP. Accordingly, a vertical distance between the bit line BL and the peripheral circuit transistor PTR may be less than a vertical distance between the cell capacitor CAP and the peripheral circuit transistor PTR.

In some embodiments, the plurality of bit lines BL may extend in the second horizontal direction Y and may be arranged such that a space between the plurality of bit lines BL is filled with a shield metal layer SS. For example, the plurality of bit lines BL may extend in the second horizontal direction Y. A portion of the shield metal layer SS may fill the space between the plurality of bit lines BL and extend in the second horizontal direction Y and another portion of the shield metal layer SS may be arranged between bottom surfaces of the plurality of bit lines BL and a top surface of the cell wiring structure 160. The sidewall and the bottom surface of the bit line BL may be covered by a first bit line insulating layer 152 and a second bit line insulating layer 154, wherein the first bit line insulating layers 152 and 154 may be arranged between the sidewall of the bit line BL and the shield metal layer SS and between the bottom surface of the bit line BL and the shield metal layer SS.

In some embodiments, the bit line BL may include titanium (Ti), titanium nitride (TiN), tantalum (Ta), tantalum nitride (TaN), molybdenum (Mo), ruthenium (Ru), tungsten (W), tungsten nitride (WN), cobalt (Co), nickel (Ni), titanium silicide (TiSi), titanium silicon nitride (TiSiN), tungsten silicide (WSi), tungsten silicon nitride (WSiN), tantalum silicide (TaSi), tantalum silicon nitride (TaSiN), ruthenium titanium nitride (RuTiN), cobalt silicide (CoSi), nickel silicide (NiSi), polysilicon, or a combination thereof. In some embodiments, the shield metal layer SS may include Ti, TiN, Ta, TaN, Mo, Ru, W, WN, Co, Ni, copper (Cu), aluminum (Al), TiSi, TiSiN, WSi, WSiN, TaSi, TaSiN, RuTiN, CoSi, NiSi, or a combination thereof.

A bit line contact 156 may be arranged between the bottom surface of the bit line BL and the cell wiring layer 162, wherein the sidewall of the bit line contact 156 may be surrounded by a bit line contact spacer 158. The bit line contact 156 may be electrically isolated from the shield metal layer SS by the bit line contact spacer 158.

A plurality of mold lines 132 and a plurality of cell transistors CTR may be arranged at a higher vertical level than the plurality of bit lines BL. For example, the plurality of mold lines 132 may each extend in the first horizontal direction X and the plurality of cell transistors CTR may be arranged on both or opposing sidewalls of each mold line 132.

The plurality of mold lines 132 are illustrated with reference to FIGS. 3 to 6 as being composed of a single material layer. However, in some embodiments, the plurality of mold lines 132 may be composed of a plurality of mold layers arranged or stacked in a vertical direction Z, wherein the material constituting each of the mold layers may vary. In some embodiments, the plurality of mold lines 132 may include at least one of silicon oxide, silicon nitride, silicon oxynitride, a low-k dielectric material.

In some embodiments, the cell transistor CTR may include a word line WL, a gate insulating layer GI, and an active semiconductor layer AP, which are sequentially arranged on the sidewall of each mold line 132.

In some embodiments, the word line WL and the active semiconductor layer AP may extend in the vertical direction Z. The gate insulating layer GI may be arranged between the word line WL and the active semiconductor layer AP. In some embodiments, a portion of the gate insulating layer GI may extend onto a bottom surface of the word line WL and onto a bottom surface the mold line 132. Accordingly, the bottom surface of the word line WL may be covered by the gate insulating layer GI.

In some embodiments, the word line WL may include Ti, TiN, Ta, TaN, Mo, Ru, W, WN, TiSiN, WSiN, polysilicon, or a combination thereof.

In some embodiments, the active semiconductor layer AP may include at least one of zinc tin oxide (ZnₓSn_{y}O), indium zinc oxide (InₓZn_{y}O), zinc oxide (ZnOₓ), indium gallium zinc oxide (InₓGa_{y}Zn_{z}O), indium gallium silicon oxide (InₓGa_{y}Si_{z}O), indium tungsten oxide (InₓW_{y}O), indium oxide (InₓO), tin oxide (SnₓO), titanium oxide (TiₓO), zinc oxynitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium Zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), and zirconium zinc tin oxide (ZrₓZn_{y}Sn_{z}O). In some embodiments, the active semiconductor layer AP may further include n-type impurity ions. For example, the n-type impurity ions may be doped into the active semiconductor layer AP through an ion implantation process or the like.

In some embodiments, the gate insulating layer GI may include at least one selected from a ferroelectric material and a high-k dielectric material having a higher dielectric constant than silicon oxide. In some embodiments, the gate insulating layer GI may include at least one material selected from hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (baTiO), lead zirconium titanium oxide (PbZrTiO), strontium bismuth tantalum oxide (SrBiTaO), bismuth iron oxide (BiFeO), strontium titanium oxide (SrTiO), yttrium oxide (YO), aluminum oxide (AlO), or lead scandium tantalum oxide (PbScTaO).

In some embodiments, a passivation layer 134 may be arranged on the sidewall of the active semiconductor layer AP. The gate insulating layer GI may be arranged on a first sidewall of the active semiconductor layer AP and the passivation layer 134 may be arranged on a second sidewall of the active semiconductor layer AP opposite to the first sidewall thereof. In some embodiments, the passivation layer 134 may include silicon oxide.

In some embodiments, as shown in FIG. 4, an upper portion of the active semiconductor layer AP may extend onto a top surface of the passivation layer 134, wherein a top surface (e.g., a top surface of the upper portion of the active semiconductor layer AP) of the active semiconductor layer AP may be arranged at a higher level than the top surface of the passivation layer 134. Accordingly, the active semiconductor layer AP may have an inverted L-shaped vertical cross-section. In other embodiments, unlike shown in FIG. 4, the upper portion of the active semiconductor layer AP may not extend onto the top surface of the passivation layer 134 and the top surface of passivation layer 134 may be arranged at the same horizontal level as (e.g., coplanar with) the top surface of the active semiconductor layer AP, wherein the active semiconductor layer AP may have a bar-shaped vertical cross-section.

In some embodiments, an insulating line 142 and a buried insulating layer 144 may be arranged on the sidewall of the passivation layer 134. The insulating line 142 and the buried insulating layer 144 may fill a space between two adjacent cell transistors CTR on the sidewall of the passivation layer 134.

A plurality of encapsulation lines EL may be disposed on the top surfaces of the plurality of bit lines BL, respectively. The plurality of encapsulation lines EL may extend in the second horizontal direction Y and cover the top surfaces of the plurality of bit lines BL, respectively. Each encapsulation line EL may be arranged between the corresponding bit line BL (i.e., a bit line BL arranged below each encapsulation line EL) and the cell transistor CTR, between the corresponding bit line BL and the mold line 132, and between the corresponding bit lines BL and the buried insulating layer 144.

In some embodiments, as shown in FIG. 6, each of the plurality of encapsulation lines EL may have a width greater than the corresponding bit line BL (i.e., a bit line BL arranged below each encapsulation line EL). For example, a first width w1 (see FIG. 6) of each of the plurality of encapsulation lines EL in the first horizontal direction X may be greater than a second width w2 (see FIG. 6) of each of the plurality of bit lines BL in the first horizontal direction X. Accordingly, a portion of the sidewall and the bottom surface of each of the plurality of encapsulation lines EL may be covered by the first bit line insulating layer 152.

In some embodiments, each of the plurality of encapsulation lines EL may have a thickness of about 1 nm to about 5 nm in the vertical direction Z.

Each of the plurality of encapsulation lines EL may have a protrusion ELP protruding in a direction toward the passivation layer 134 (an upward or vertical/Z-direction in FIG. 4) and away from the bit line BL. In some embodiments, the sidewall of the protrusion ELP may contact a lower portion of a sidewall AP_S of the active semiconductor layer AP and the top surface of the protrusion ELP may contact the bottom surface of the passivation layer 134. The top surface of the protrusion ELP may be arranged at a higher vertical level than the top surface of each encapsulation line EL or the bottom surface of the active semiconductor layer AP.

In some embodiments, the plurality of encapsulation lines EL may include a first metal. The first metal may include at least one of Ta, niobium (Nb), and Al. In some embodiments, the first metal constituting the plurality of encapsulation lines EL may include a metal material with excellent oxidation capability. In some embodiments, the first metal constituting the plurality of encapsulation lines EL may include a metal material with relatively low hydrogen diffusivity through the first metal. The first metal constituting the plurality of encapsulation lines EL may further include any other metal material with excellent oxidation capability and relatively low hydrogen diffusivity, in addition to Ta, Nb, and Al, described above.

In some embodiments, each of the plurality of encapsulation lines EL may be in contact with a bottom surface AP_B of the active semiconductor layer AP and a lower portion of the sidewall AP_S of the active semiconductor layer AP. Each of the plurality of encapsulation lines EL may include an oxide region PO defined inside the encapsulation line EL adjacent to an interface in contact with the bottom surface AP_B and the lower portion of the sidewall AP_S of the active semiconductor layer AP. For example, the oxide region PO may have a thickness of about 0.1 nm to about 2 nm from an interface between the encapsulation line EL and the bottom surface AP_B of the active semiconductor layer AP and an interface between the encapsulation line EL and the lower portion of the sidewall AP_S of the active semiconductor layer AP.

In some embodiments, the first metal constituting the plurality of encapsulation lines EL may have excellent oxidation capabilities. Accordingly, the oxidation reaction of the first metal may occur inside the encapsulation line EL adjacent to the interface in contact with the bottom surface AP_B and the lower portion of the sidewall AP_S of the active semiconductor layer AP to form the oxide region PO. An oxygen vacancy may be formed inside the active semiconductor layer AP adjacent to the interface in contact with the encapsulation line EL while the oxide region PO is formed in the plurality of encapsulation lines EL. Accordingly, the electrical conductivity of the contact region between the active semiconductor layer AP and the bit line BL may be improved and the on-current of the cell transistor CTR may be increased.

In some embodiments, the first metal constituting the plurality of encapsulation lines EL may include a metal material with relatively low hydrogen diffusivity through the first metal. Since the bottom surface of the active semiconductor layer AP is completely covered by the plurality of encapsulation lines EL, the influence of hydrogen ions which can flow into the active semiconductor layer AP from the bit line BL may be reduced or eliminated or controlled. Therefore, the semiconductor device 100 may have excellent reliability.

FIGS. 5 and 6 illustrate the case where the oxide region PO is formed in a portion of the plurality of encapsulation lines EL, that is, the case where the thickness of the oxide region PO in the vertical direction Z is less than the thickness of the encapsulation line EL in the vertical direction Z. However, in other embodiments, a relatively large concentration of oxygen may diffuse from the active semiconductor layer AP, thereby increasing the oxidation level of the encapsulation line EL. In this case, the thickness of the oxide region PO in the vertical direction Z may be similar to or the same as the thickness of the encapsulation line EL.

A plurality of landing pads LP may be disposed on the plurality of cell transistors CTR, respectively. A spacer 172 may be formed on the plurality of cell transistors CTR, for example, on the sidewall of the active semiconductor layer AP. A landing pad LP in contact with the top surface of the active semiconductor layer AP may be disposed on the spacer 172. The sidewall of the landing pad LP may be surrounded by a landing pad insulating layer 174. The cell capacitor CAP may be disposed on each landing pad LP, wherein an insulating layer 176 may be disposed on at least a portion of the cell capacitor CAP.

In some embodiments, the plurality of landing pads LP may include Ti, TiN, Ta, TaN, W, WN, TiSiN, WSiN, polysilicon, or a combination thereof. In some embodiments, the cell capacitor CAP may have a metal-insulator-metal type capacitor structure. For example, the cell capacitor CAP may include a first electrode, a second electrode, and a capacitor dielectric layer between the first electrode and the second electrode.

According to some embodiments, the oxide region PO may be formed in a portion of the encapsulation line EL. The on-state current of the cell transistor CTR may be increased by forming the oxygen vacancy in the portion of the active semiconductor layer AP in contact with the encapsulation line EL. In addition, the encapsulation line EL may prevent hydrogen ions from flowing from the bit line BL into the active semiconductor layer AP of the cell transistor CTR, thereby improving the reliability of the semiconductor device 100.

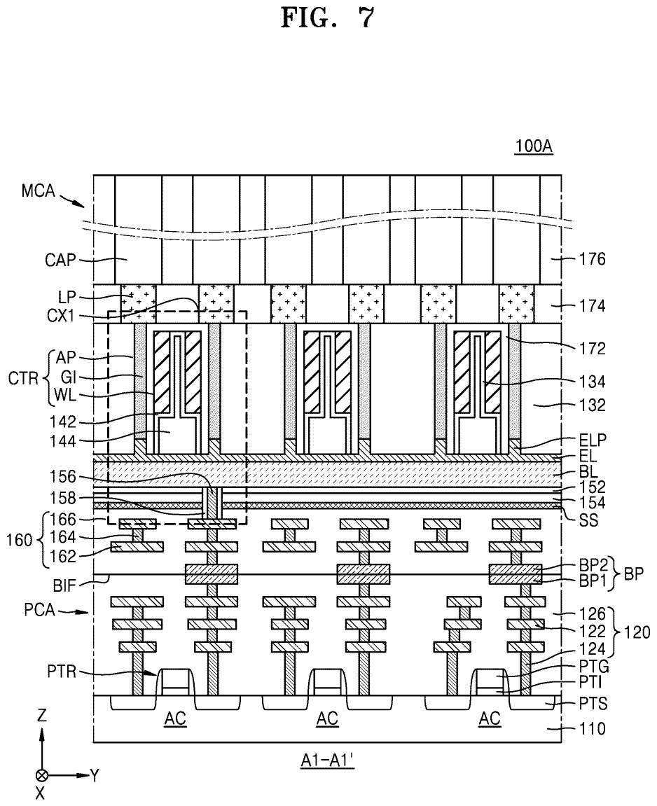

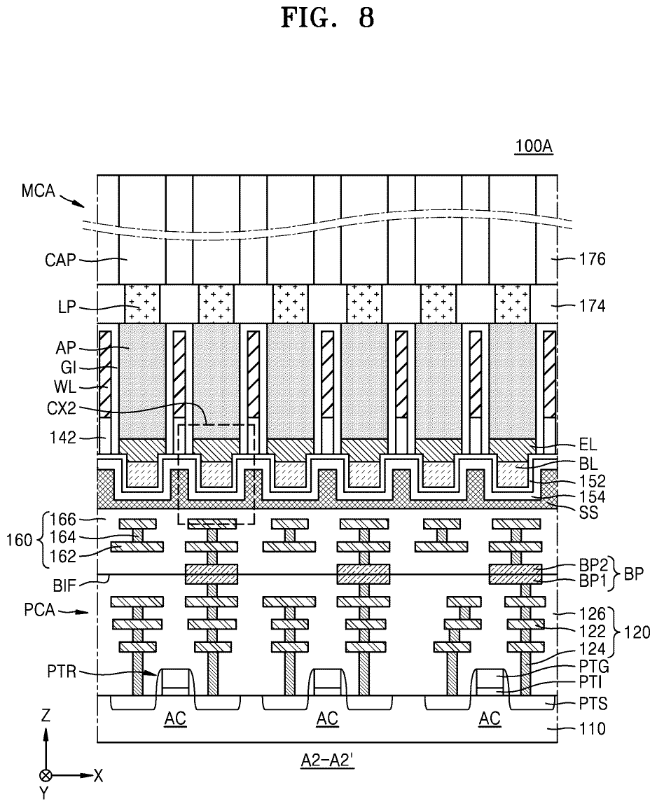

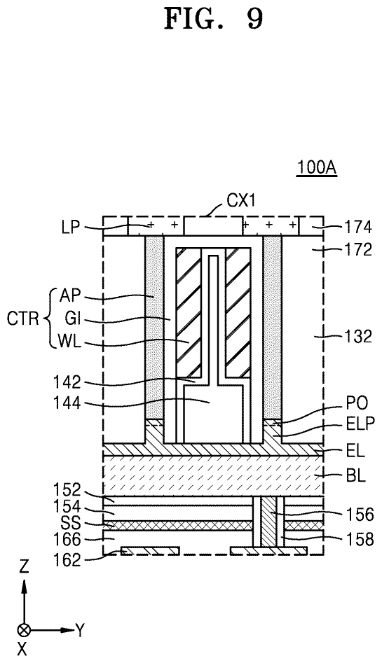

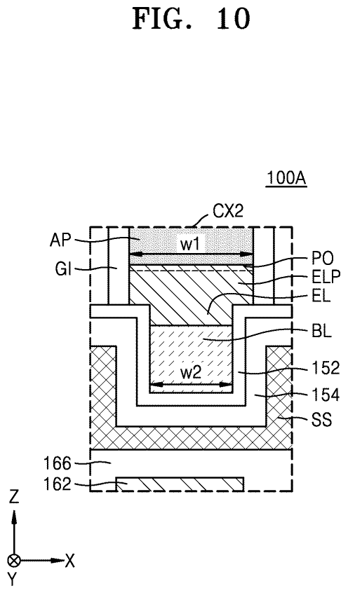

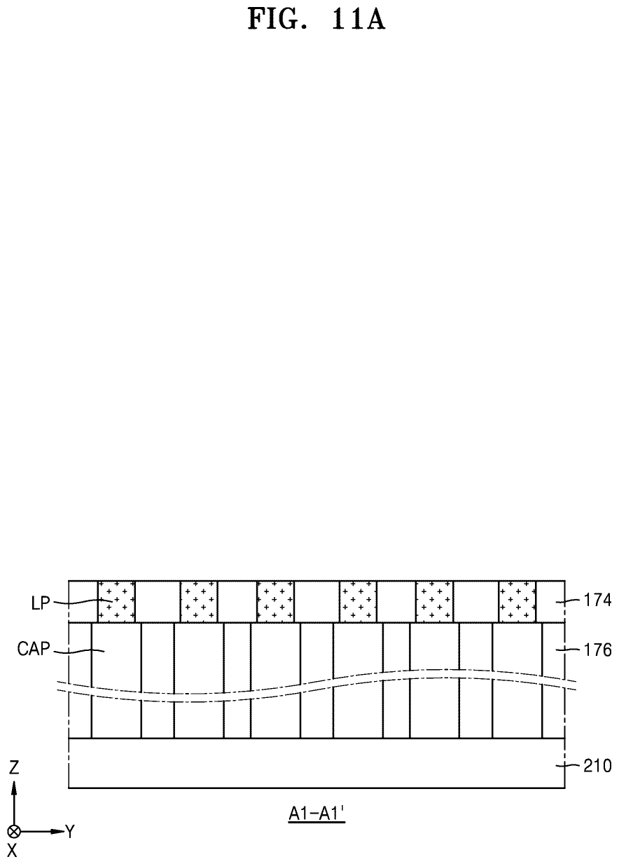

FIGS. 7 and 8 are cross-sectional views of a semiconductor device 100A according to some embodiments. FIG. 9 is an enlarged view of portion CX1 in FIG. 7. FIG. 10 is an enlarged view of portion CX2 in FIG. 8.

Referring to FIG. 7 to FIG. 10, the cell transistor CTR may be arranged on the sidewall of the mold line 132. The active semiconductor layer AP, the gate insulating layer GI, and the word line WL may be sequentially arranged on the sidewall of the mold line 132. The active semiconductor layer AP may have a top surface arranged at the same level as the top surface of the mold line 132 and may have a bottom surface arranged at a higher level than the bottom surface of the mold line 132, e.g., relative to the bit line BL. The gate insulating layer GI may extend from the sidewall of the active semiconductor layer AP, wherein a portion of the gate insulating layer GI may extend onto the top surface of the word line WL. The insulating line 142 and the buried insulating layer 144 may fill a space between two adjacent word lines WL.

The encapsulation line EL may be arranged between the bit line BL and the cell transistor CTR and between the bit line BL and the mold line 132. The encapsulation line EL may include the protrusion ELP protruding upward (e.g., in the vertical or Z-direction), wherein a top surface of the protrusion ELP may be in contact with the bottom surface of the active semiconductor layer AP. The protrusion ELP may vertically overlap with the active semiconductor layer AP. Components or layers described with reference to “overlap” in a particular direction may be at least partially obstructed by one another when viewed along a line extending in the particular direction or in a plane perpendicular to the particular direction. The sidewalls (e.g., opposing sidewalls spaced apart from each other in the second horizontal direction Y shown in FIG. 9 and opposing sidewalls separated from each other in the first horizontal direction X shown in FIG. 10) of the protrusion ELP may be in contact with the gate insulating layer GI or the mold line 132.

As shown in FIG. 9, the oxide region PO may be formed inside the encapsulation line EL (e.g., inside the protrusion ELP) around the interface in contact with the active semiconductor layer AP. In some embodiments, as the entire bottom surface of the active semiconductor layer AP is in contact with the top surface of the protrusion ELP, the entire top surface of the protrusion ELP may be included in the oxide region PO.

As shown in FIG. 10, the protrusion ELP of the encapsulation line EL has the first width w1, wherein the first width w1 may be greater than the second width w2 of the bit line BL. In some embodiments, during a patterning process of the bit line BL, a lower portion of the encapsulation line EL may also be patterned. Thus, the lower portion of the encapsulation line EL may have the same width as the bit line BL and a step may be formed on a side of the encapsulation line EL, as shown in FIG. 10. In other embodiments, unlike shown in FIG. 10, the lower portion of the encapsulation line EL may be formed to have the same width as the first width w1 of the protrusion ELP and the step may not be formed on the side of the encapsulation line EL.

The semiconductor devices described with reference to FIGS. 1 to 10 may have a cell-on-periphery structure in which the peripheral circuit area PCA is disposed on the cell array area MCA. In other embodiments, the semiconductor device may have a periphery-on-cell structure in which the peripheral circuit area PCA is disposed on the cell array area MCA and the peripheral circuit area PCA is electrically connected to the cell array area MCA by a through via passing through the substrate 110.

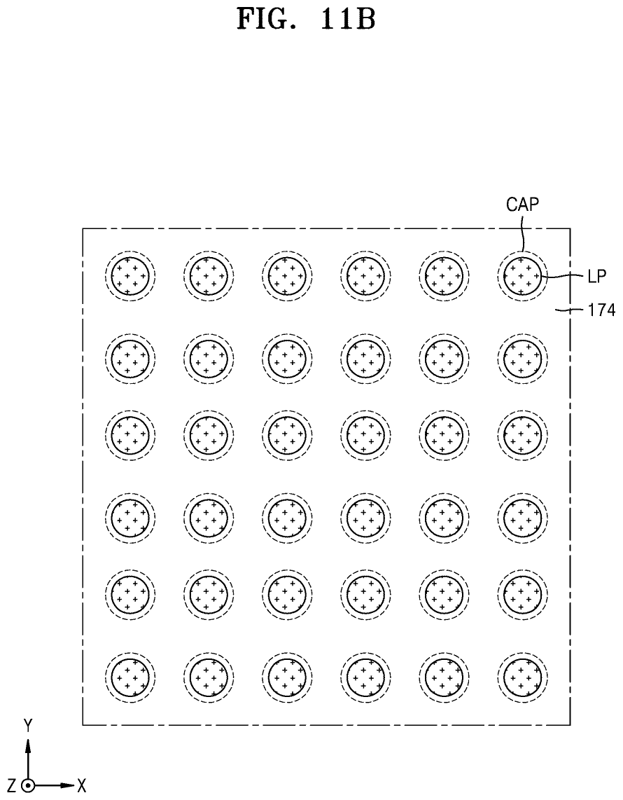

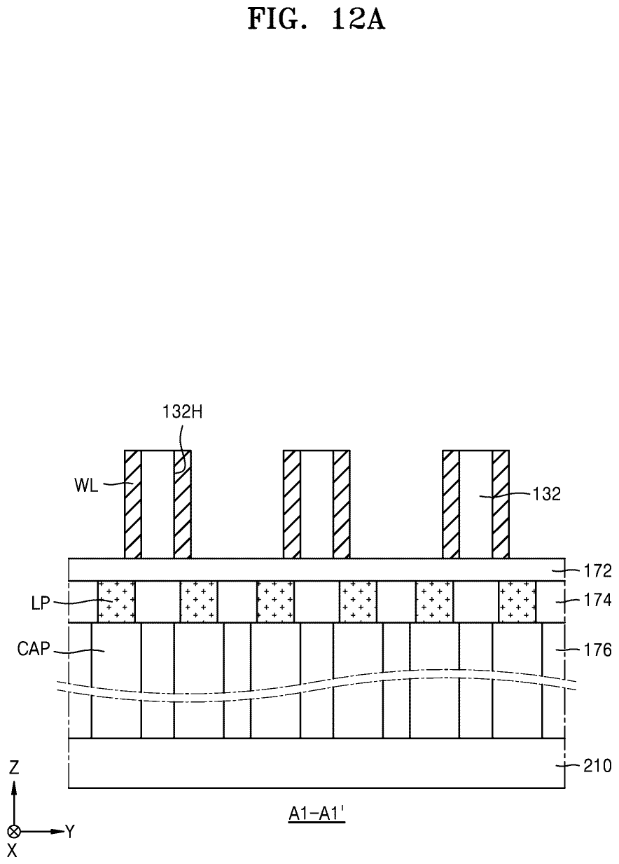

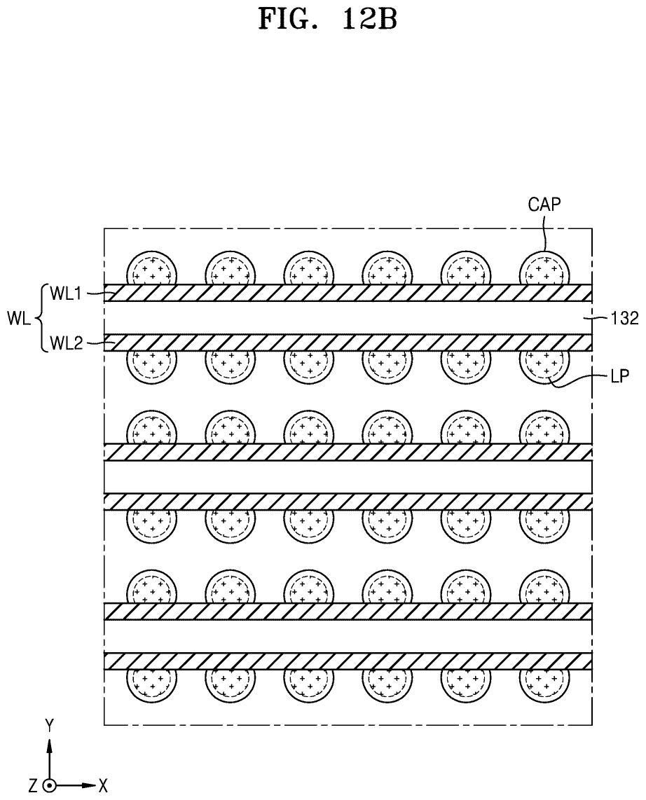

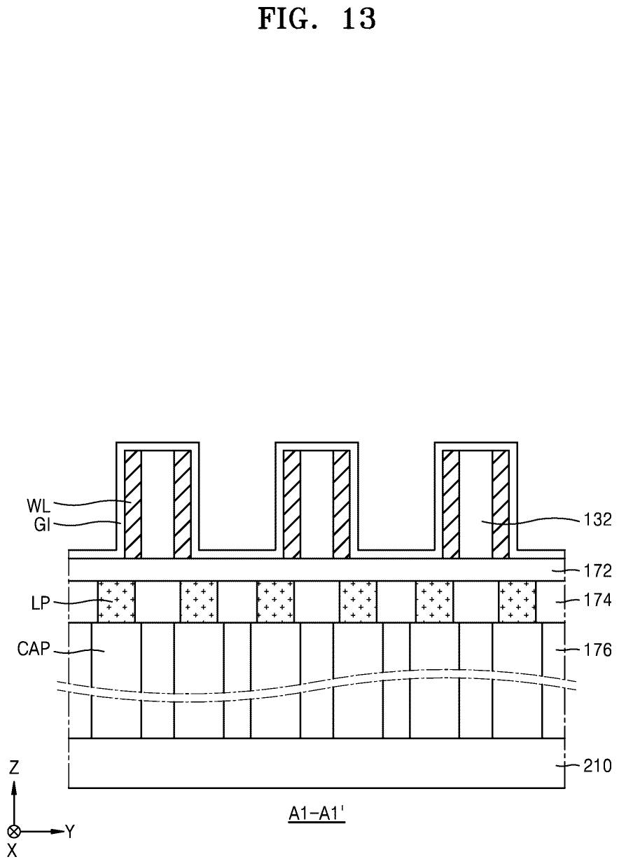

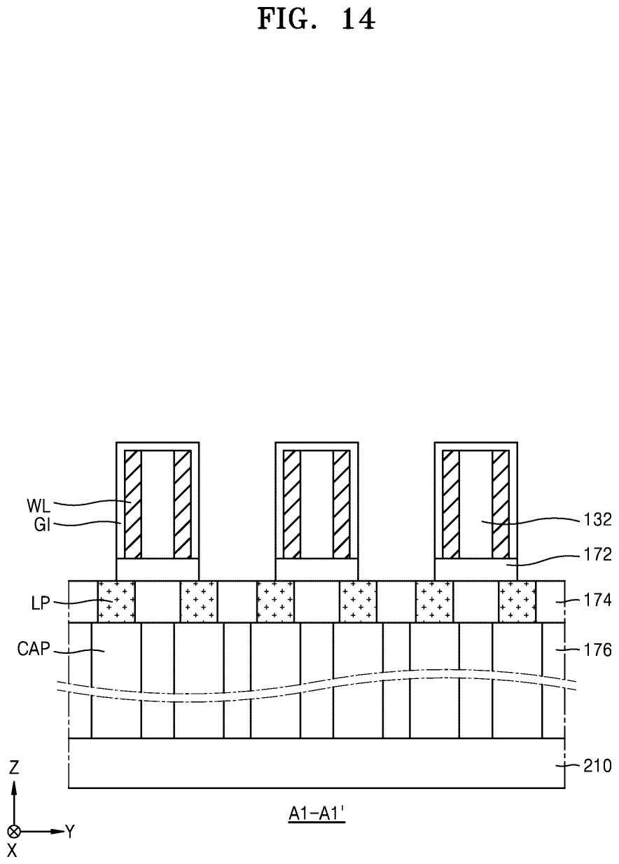

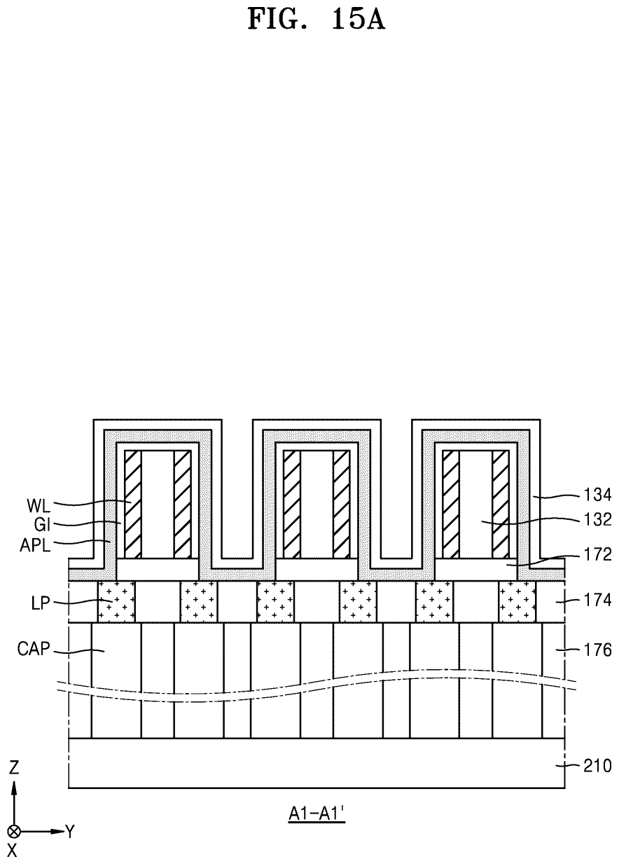

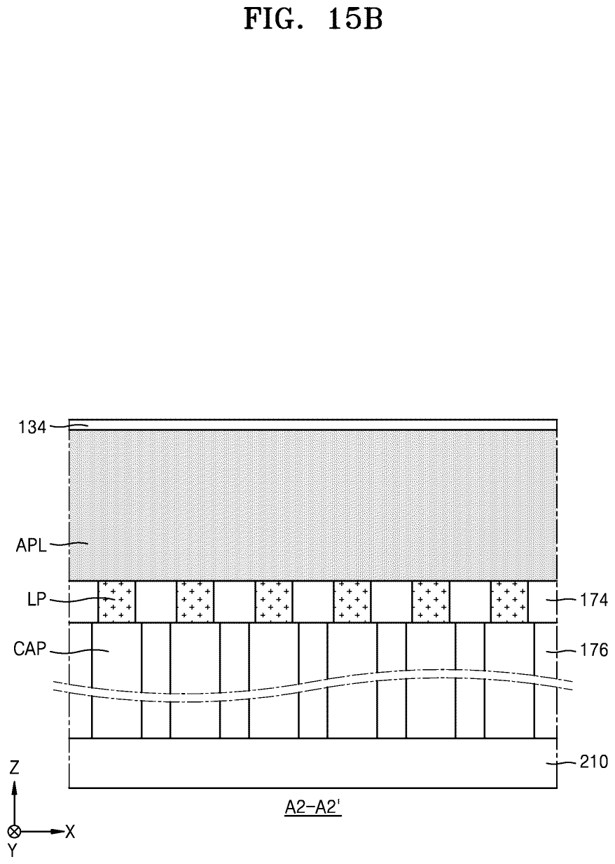

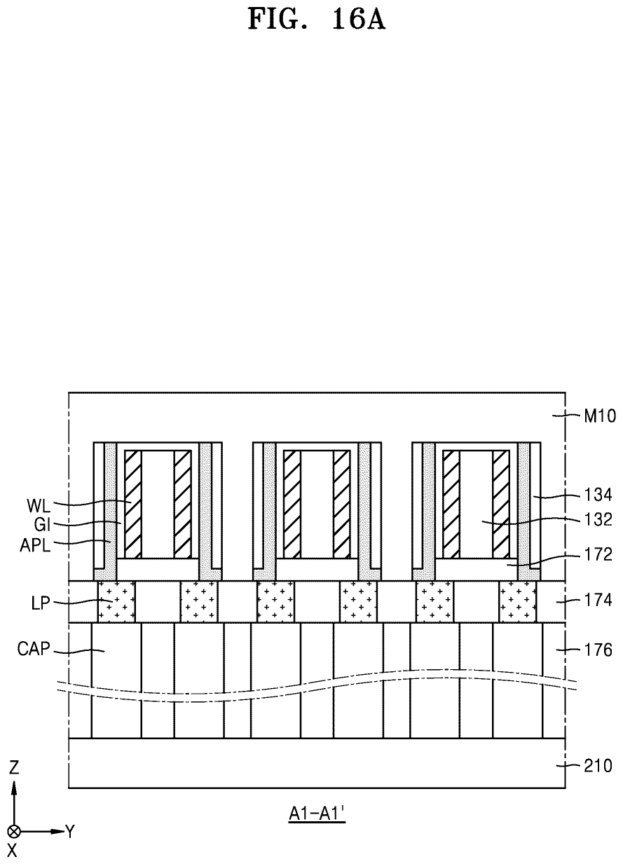

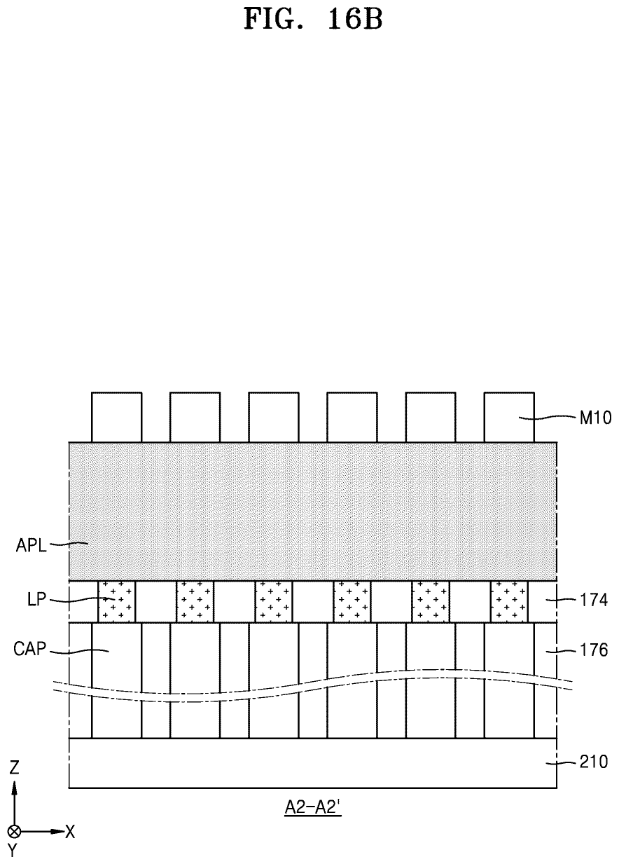

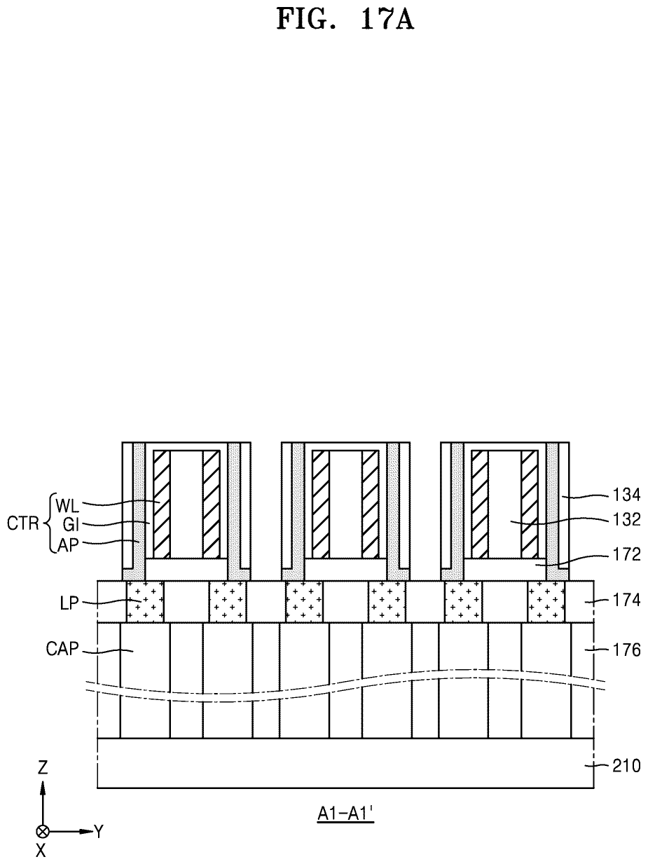

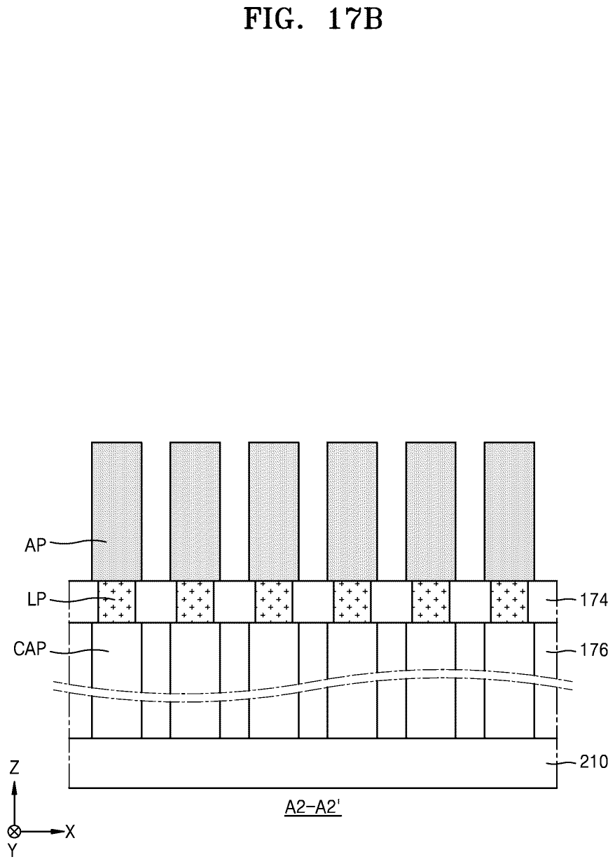

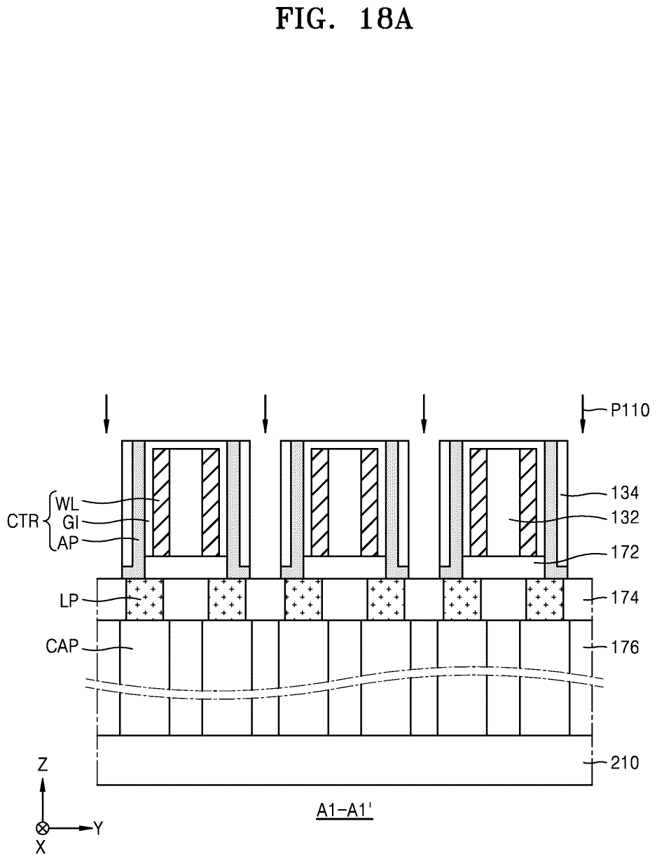

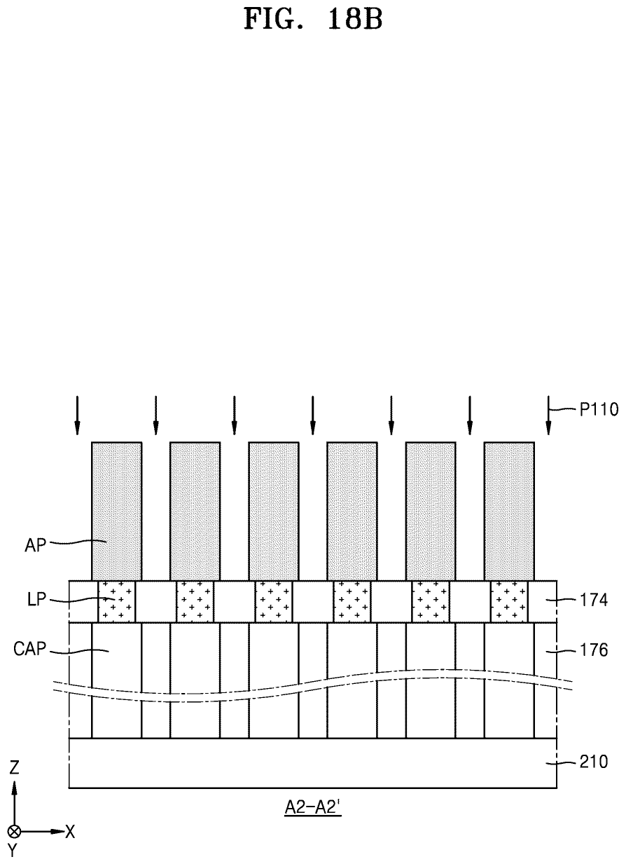

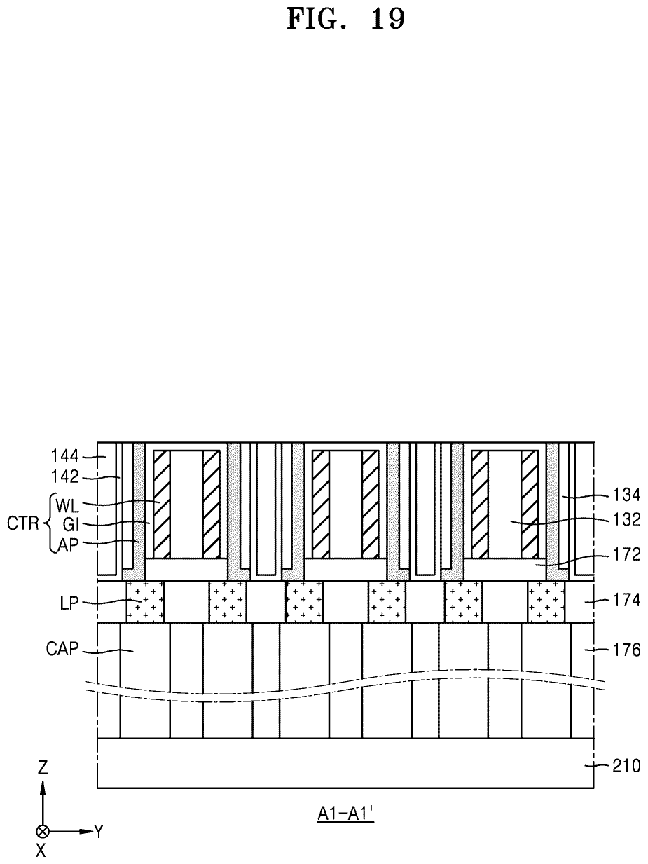

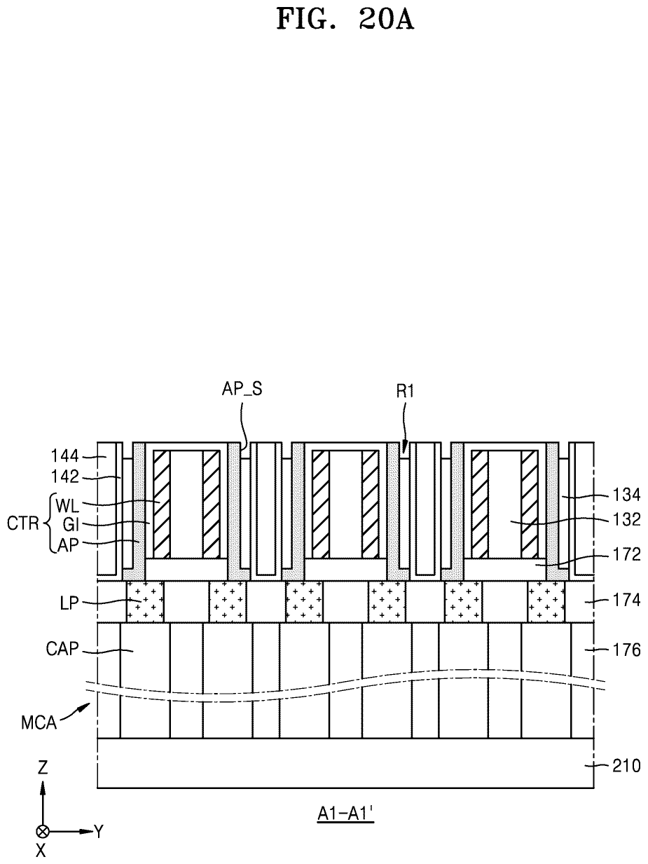

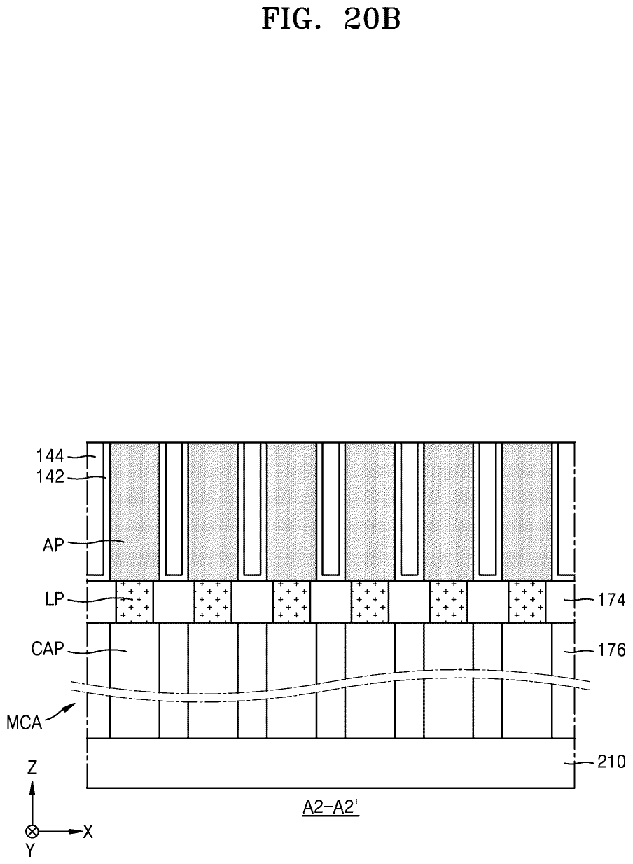

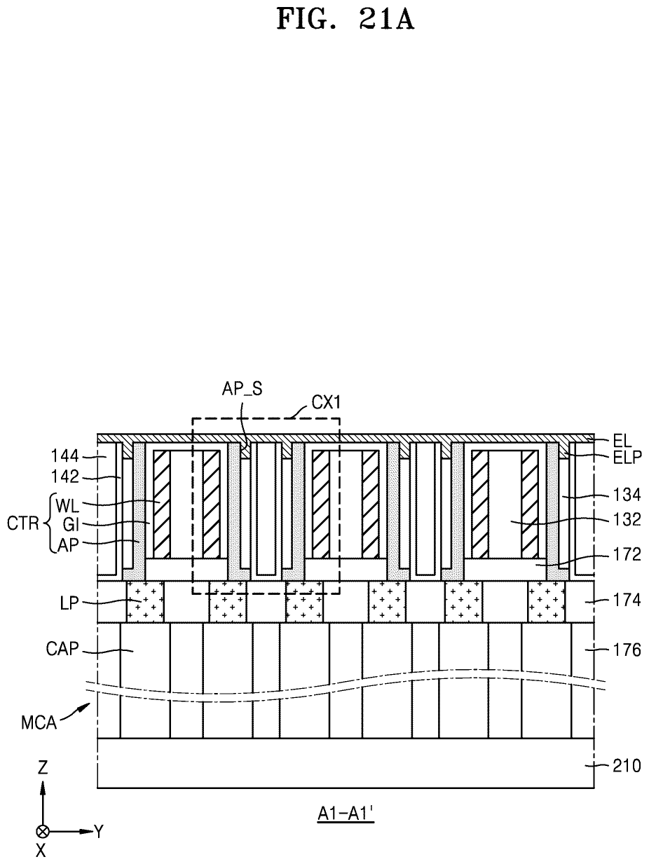

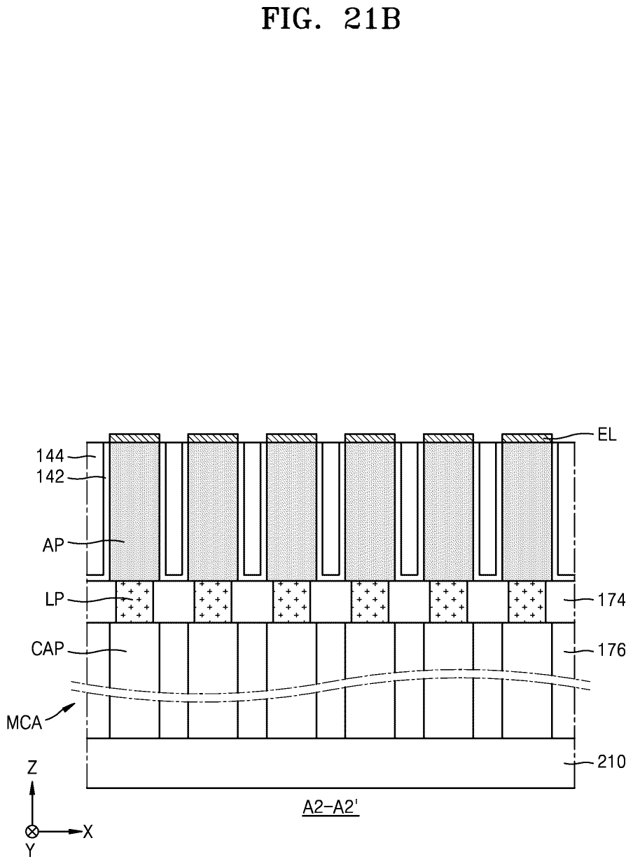

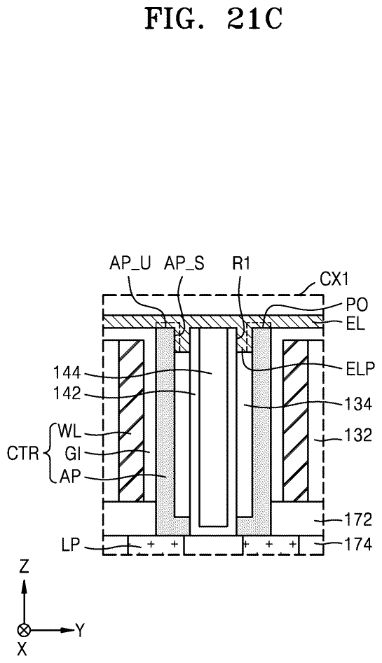

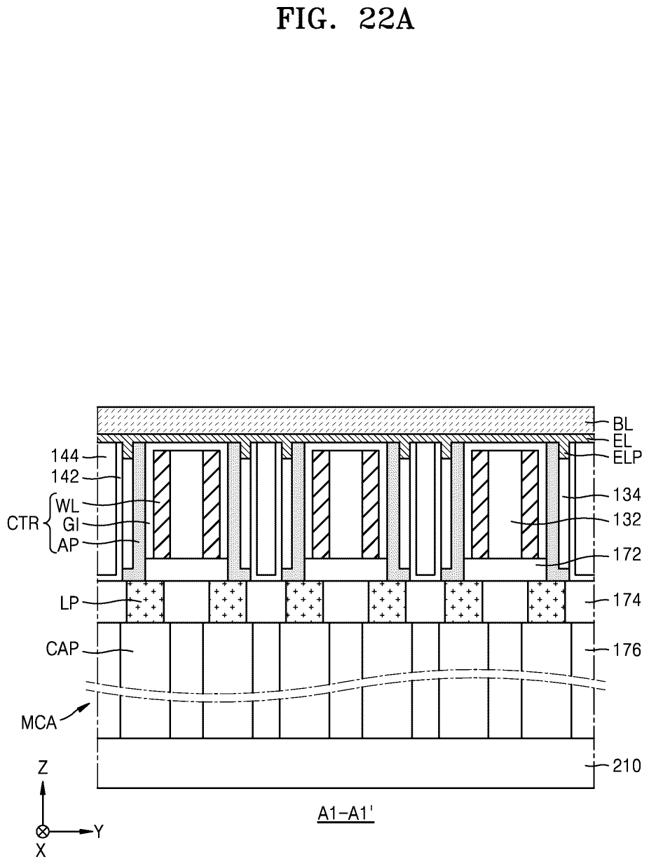

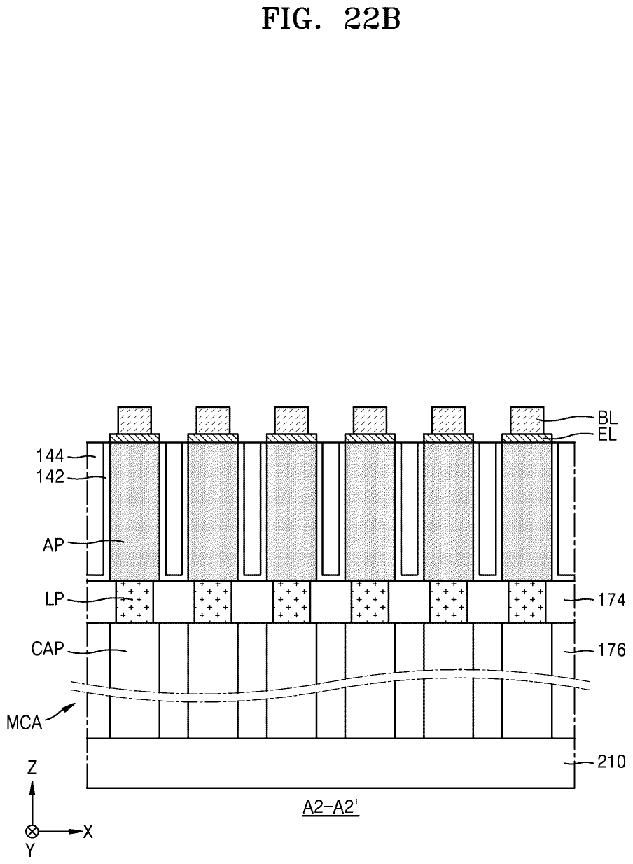

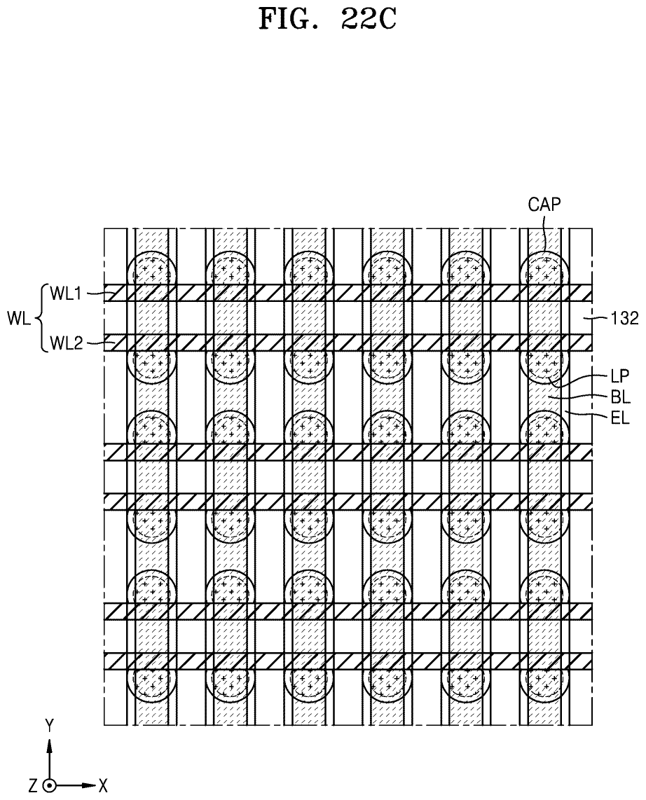

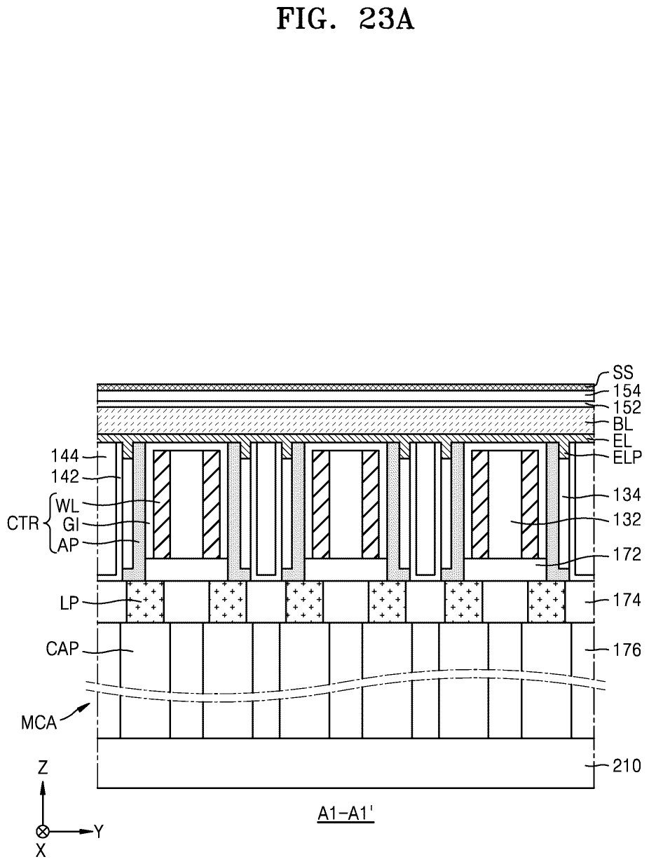

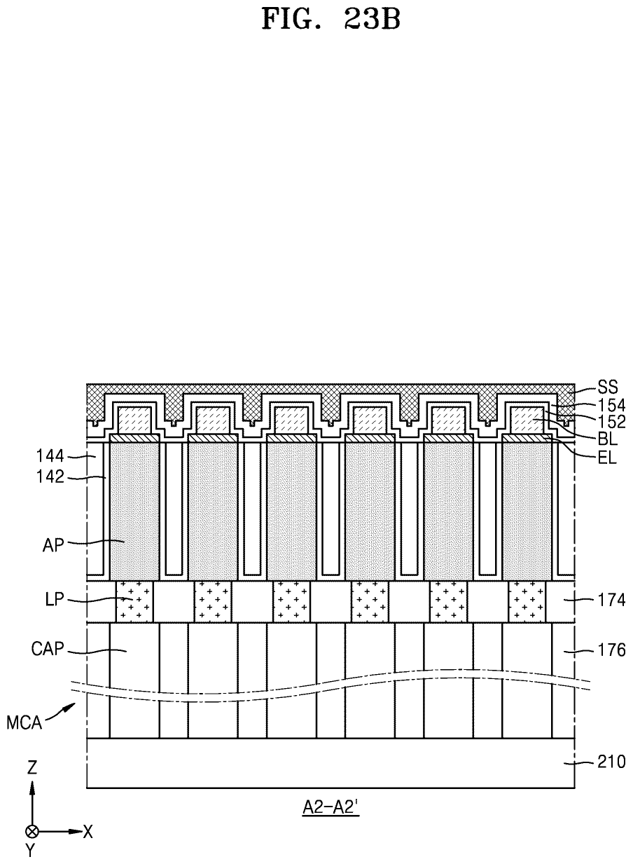

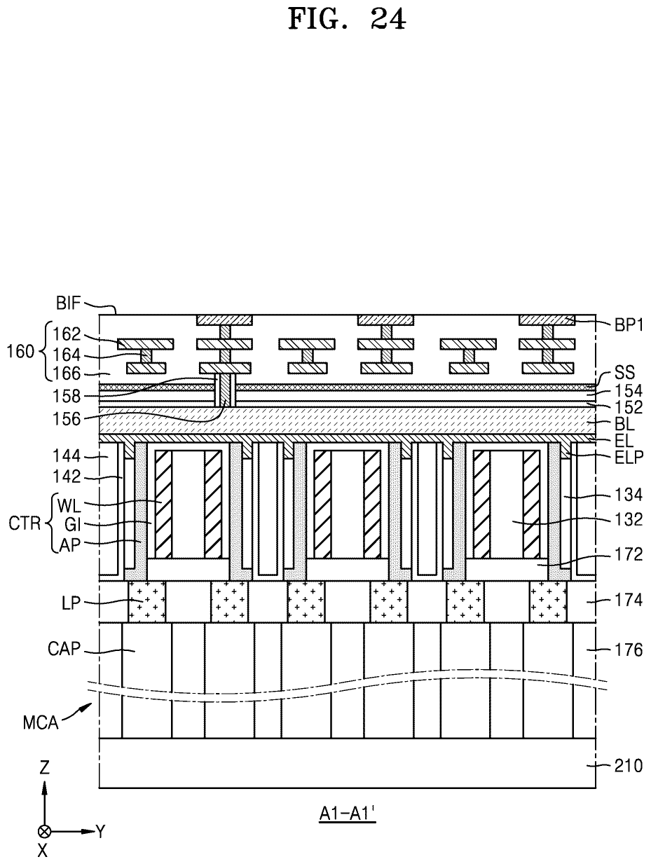

FIGS. 11A to 26 are schematic diagrams illustrating a method of manufacturing the semiconductor device 100, according to some embodiments. Specifically, FIG. 11A, FIG. 12A, FIG. 13, FIG. 14, FIG. 15A, FIG. 16A, FIG. 17A, FIG. 18A, FIG. 19, FIG. 20A, FIG. 21A, FIG. 22A, FIG. 23A, and FIG. 24 to 26 are cross-sectional views taken along line A1-A1′ in FIG. 2; FIG. 15B, FIG. 16B, FIG. 17B, FIG. 18B, FIG. 20B, FIG. 21B, FIG. 22B, and FIG. 23B are cross-sectional views taken along line A2-A2′ in FIG. 2; FIG. 11B, FIG. 12B, and FIG. 22C are plan views corresponding to the cross-sectional views of FIGS. 11A, 12A, and 22A, respectively; and FIG. 21C is an enlarged view of portion CX1 in FIG. 21A.

Referring to FIGS. 11A and 11B, the cell capacitor CAP may be formed on a carrier substrate 210, and the insulating layer 176 may be formed to surround the sidewall of the cell capacitor CAP. Thereafter, the landing pad LP connected to the cell capacitor CAP may be formed, and the landing pad insulating layer 174 covering the sidewall and the top surface of the landing pad LP may be formed.

In some embodiments, a capacitor mold insulating layer may be formed on the carrier substrate 210, a capacitor opening extending in the vertical direction Z may be formed in the capacitor mold insulating layer, and the cell capacitor CAP may be formed within the capacitor opening.

In some embodiments, as shown in FIG. 11B, the cell capacitor CAP and the landing pad LP may be arranged in a matrix shape (e.g., arranged in rows and columns) in plan view. In other embodiments, the cell capacitor CAP and the landing pad LP may be arranged in a hexagon shape (e.g., arranged at respective vertices of a hexagon) in plan view.

Referring to FIGS. 12A and 12B, the spacer 172 may be formed on the landing pad LP and the landing pad insulating layer 174. In some embodiments, the spacer 172 may cover the entire top surface of the landing pad LP and the landing pad insulating layer 174 and may be formed using silicon nitride.

Thereafter, the mold line 132 may be formed by forming a mold insulating layer on the spacer 172, forming a mask pattern on the mold insulating layer, and patterning the mold insulating layer using the mask pattern. In some embodiments, the mold line 132 may extend in the first horizontal direction X, and the mold line 132 may include a sidewall 132H extending in the first horizontal direction X.

In some embodiments, the width of the mold line 132 in the second horizontal direction Y may be determined such that two landing pads LP are arranged between two adjacent mold lines 132 in the second horizontal direction Y.

The word line WL may then be formed on both or opposing sidewalls of the mold line 132.

In some embodiments, a word line conductive layer may be formed on the sidewall 132H and the top surface of the mold line 132, and the top surface of the spacer 172. An anisotropic etching process or an etch-back process may be performed on the word line conductive layer to remove a portion of the word line conductive layer and leave the word line WL on both or opposing sidewalls of the mold line 132.

Referring to FIG. 13, the gate insulating layer GI may be formed on the top surface of the mold line 132, both or opposing sidewalls of the word line WL, and the top surface of the spacer 172.

Referring to FIG. 14, a mask pattern may be formed on the gate insulating layer GI and a portion of the spacer 172 may be removed by using the mask pattern as an etching mask to expose the top surface of the landing pad LP.

Referring to FIGS. 15A and 15B, a preliminary active semiconductor layer APL may be formed on the sidewall of the mold line 132, and the passivation layer 134 may be formed on the preliminary active semiconductor layer APL. A portion of the preliminary active semiconductor layer APL may be disposed on the top surface of the mold line 132 with the gate insulating layer GI therebetween, another portion of the preliminary active semiconductor layer APL may be arranged on the sidewall of the mold line 132 with the gate insulating layer GI therebetween, and the other portion of the preliminarily active semiconductor layer APL may be in direct contact with the top surface of the landing pad LP.

In some embodiments, the passivation layer 134 may be formed using silicon oxide. The passivation layer 134 may conformally cover the entire top surface of the preliminary active semiconductor layer APL.

Referring to FIGS. 16A and 16B, an etch-back process may be performed on the passivation layer 134 and the preliminary active semiconductor layer APL to remove a portion of the passivation layer 134 disposed on the top surface of the mold line 132 and a portion of the preliminary active semiconductor layer APL disposed on the top surface of the mold line 132. In addition, a portion of the passivation layer 134 disposed on the top surface of the landing pad insulating layer 174 and a portion of the preliminary active semiconductor layer APL disposed on the top surface of the landing pad insulating layer 174may be removed.

In some embodiments, the gate insulating layer GI disposed on the top surface of the mold line 132 may not be removed during the etch-back process. After the etch-back process, the top surface of the preliminary active semiconductor layer APL may be arranged at the same vertical level as (e.g., coplanar with) the top surface of the gate insulating layer GI and the top surface of the passivation layer 134.

In some embodiments, the sidewall of the preliminary active semiconductor layer APL may be covered by the passivation layer 134. As the passivation layer 134 remains on the sidewall of the preliminary active semiconductor layer APL, a portion (a portion extending in the second horizontal direction Y) of the preliminary active semiconductor layer APL arranged below the bottom surface of the passivation layer 134 may not be removed during the patterning process. As shown in FIG. 16A, the preliminary active semiconductor layer APL may have an L-shaped vertical cross-section.

Thereafter, a mold mask pattern M10 may be formed on the preliminary active semiconductor layer APL and the passivation layer 134. The mold mask pattern M10 may fill a space between two adjacent preliminary active semiconductor layers APL and may have a line pattern shape extending in the second horizontal direction Y. In some embodiments, the mold mask pattern M10 may have a double layer structure of a lower mask layer and an upper mask layer. In some embodiments, the lower mask layer may include a silicon-on-hard mask and the upper mask layer may include silicon oxynitride.

Referring to FIGS. 17A and 17B, a portion of the passivation layer 134 and a portion of the preliminary active semiconductor layer APL that are not covered by the mold mask pattern M10 may be removed. Other portions of the preliminary active semiconductor layer APL that are covered by the mold mask pattern M10 may not be removed, which may be referred to as the active semiconductor layers AP. The active semiconductor layers AP between two adjacent mold lines 132 may be spaced apart from each other in the first horizontal direction X and/or in the second horizontal direction Y, and one active semiconductor layer AP may be disposed on one landing pad LP.

Referring to FIGS. 18A and 18B, an annealing process P110 may be performed on a structure where the active semiconductor layer AP is formed. In some embodiments, the annealing process P110 may be performed in an atmosphere containing oxygen. In some embodiments, the annealing process P110 may be performed by supplying at least one of oxygen gas, ozone gas, H₂O₂ gas, oxygen radical, oxygen plasma to a structure where the active semiconductor layer AP is formed. In some embodiments, the annealing process P110 may be performed at a temperature of room temperature to 300° C. In some embodiments, the annealing process P110 may be performed to supply oxygen atoms through the passivation layer 134 into the active semiconductor layer AP.

Referring to FIG. 19, the insulating line 142 may be formed in a space between two adjacent passivation layers 134, and the buried insulating layer 144 may be formed on the insulating line 142 to fill the space between the two adjacent passivation layers 134.

Referring to FIGS. 20A and 20B, an upper portion of the passivation layer 134 may be removed to form a recess R1 on the upper portion of the passivation layer 134. By forming the recess R1, the sidewall AP_S of the active semiconductor layer AP may be exposed. The recess R1 may refer to a space defined by the sidewall AP_S of the active semiconductor layer AP, the sidewall of the insulating line 142, and the top surface of the passivation layer 134.

In some embodiments, the recess R1 may be formed by forming a mask pattern that exposes the top surface of the passivation layer 134 and removing a portion of the passivation layer 134 using the mask pattern as an etch mask.

Referring to FIGS. 21A to 21C, the encapsulation line EL may be formed by forming a conductive layer on the top surface of the active semiconductor layer AP, forming a mask pattern on the conductive layer, and patterning the conductive layer using the mask pattern as an etching mask.

In some embodiments, the encapsulation line EL may have a first width w1 (see FIG. 5) greater than the width of the active semiconductor layer AP in the second horizontal direction Y to cover the top surface of each active semiconductor layer AP and may extend in the second horizontal direction Y. In addition, a portion of the encapsulation line EL may fill the inside of the recess R1, wherein the portion of the encapsulation line EL inside the recess R1 may be referred to as a protrusion ELP.

In some embodiments, the encapsulation line EL may include a first metal, wherein the first metal may include at least one of Ta, Nb, and Al. In some embodiments, the process for forming the encapsulation line EL may be performed using at least one of a chemical vapor deposition (CVD) process, an atomic layer deposition (ALD) process, an evaporation process, and a sputtering process. In some embodiments, the first metal may include a material with excellent oxidation capability and/or may include a material with low diffusivity of hydrogen atoms or hydrogen ions through the first metal.

As shown in FIG. 21C, the oxide region PO may be formed inside the encapsulation line EL at portions of the encapsulation line extending along an interface with or otherwise in contact with the active semiconductor layer AP. In some embodiments, the oxidation reaction of the first metal may occur inside the encapsulation line EL adjacent to the interface in contact with the upper portion of the sidewall AP_S and the top surface AP_U of the active semiconductor layer AP to form the oxide region PO. In some embodiments, the oxide region PO may include a metal oxide formed by oxidation of the first metal. For example, the oxide region PO may include at least one of TaO, niobium oxide (NbO), AlO.

The oxygen vacancy may be formed inside the portions or regions of the active semiconductor layer AP adjacent to the interface(s) in contact with the encapsulation line EL, while the oxide region PO is formed in the portions or regions of the plurality of encapsulation lines EL that are adjacent to the interface(s) in contact with the active semiconductor layers AP. Accordingly, the electrical conductivity of the contact region or interfaces between the active semiconductor layer AP and the bit line BL may be improved and the on-current of the cell transistor CTR may be increased.

Referring to FIGS. 22A and 22B, the bit line BL may be formed on the encapsulation line EL.

In some embodiments, the bit line BL may include Ti, TiN, Ta, TaN, Mo, Ru, W, WN, Co, Ni, TiSi, TiSiN, WSi, WSiN, TaSi, TaSiN, RuTiN, CoSi, NiSi, polysilicon, or a combination thereof.

In some embodiments, to form the bit line BL, a bit line conductive layer may be formed on top surfaces of the encapsulation line EL and the buried insulating layer 144, a mask pattern may be formed on the bit line conductive layer, and the bit line conductive layer may be patterned using the mask pattern. In some embodiments, in the process of forming the bit line conductive layer and/or the process of patterning the bit line conductive layer, diffusion of hydrogen ions into the active semiconductor layer AP may be reduced and/or prevented as the encapsulation line EL completely covers the top surface of the active semiconductor layer AP.

Referring to FIGS. 23A and 23B, the first bit line insulating layer 152 and the second bit line insulating layer 154 may be sequentially formed on the encapsulation line EL and the bit line BL, and the shield metal layer SS may be formed on the second bit line insulating layer 154.

Referring to FIG. 24, the cell wiring structure 160 may be formed on the shield metal layer SS. The cell wiring structure 160 may include the cell wiring layer 162, the cell via 164, and the cell insulating layer 166. In addition, the bit line contact 156 may be formed to connect the cell wiring layer 162 to the bit line BL. The sidewall of the bit line contact 156 may be surrounded by the bit line contact spacer 158. The bit line contact 156 may be electrically insulated from the shield metal layer SS by the bit line contact spacer 158.

The first bonding pad BP1 may be provided in the cell insulating layer 166 of the cell wiring structure 160. The first bonding pad BP1 may be electrically connected to the cell wiring layer 162, for example, by the cell vias 164. The top surface of the cell insulating layer 166 may be arranged on the same plane as or coplanar with the top surface of the first bonding pad BP1 and the top surface of the cell insulating layer 166 may be referred to as the bonding interface BIF.

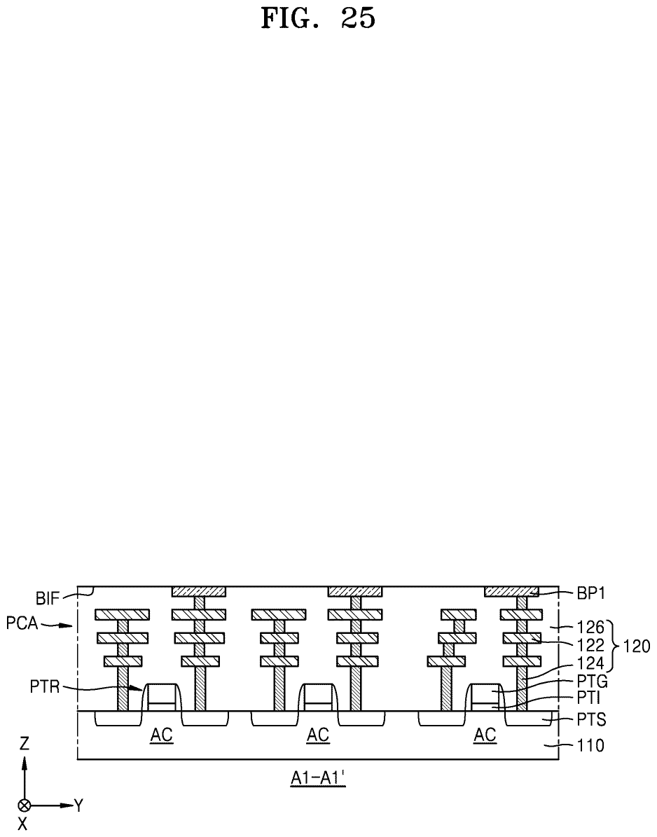

Referring to FIG. 25, the active region AC may be formed on the substrate 110 and the peripheral circuit transistor PTR may be formed on the active region AC. For example, the peripheral circuit transistor PTR may include the gate electrode PTG, the gate insulating layer PTI, and the source/drain region PTS.

Thereafter, the peripheral circuit wiring 122 and the peripheral circuit contact 124 electrically connected to the substrate 110 and the peripheral circuit transistor PTR may be formed, and the peripheral circuit insulating layer 126 covering the peripheral circuit wiring 122 and the peripheral circuit contact 124 may be formed on the substrate 110. The peripheral circuit insulating layer 126 may be formed using an oxide film, a nitride film, a low-k dielectric film, or a combination thereof.

The second bonding pad BP2 may be provided in the peripheral circuit insulating layer 126. The second bonding pad BP2 may be electrically connected to the peripheral circuit wiring 122, for example, by the peripheral circuit contacts 124. The top surface of the peripheral circuit insulating layer 126 may be arranged on the same plane as or coplanar with the top surface of the second bonding pad BP2, and the top surface of the peripheral circuit insulating layer 126 may be referred to as the bonding interface BIF.

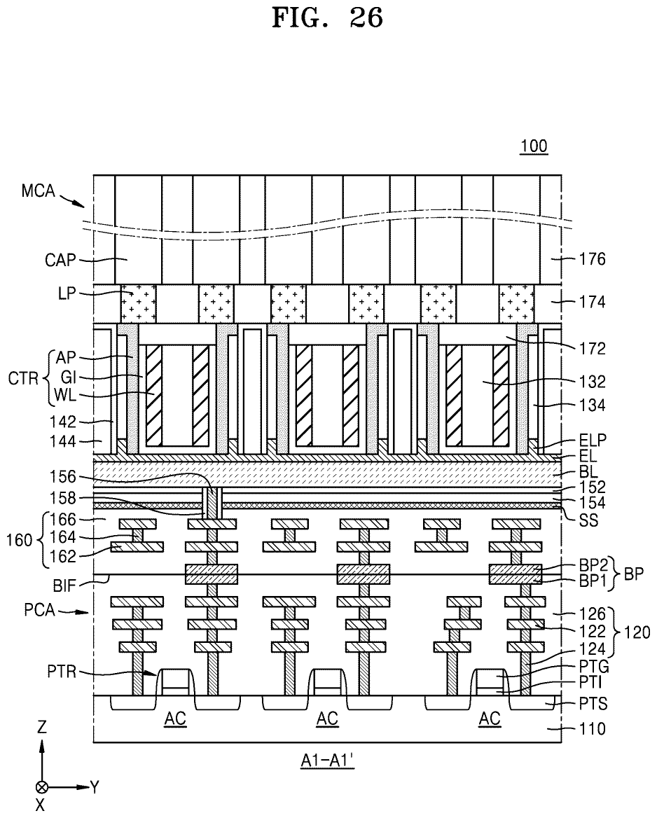

Referring to FIG. 26, the peripheral circuit area PCA and the cell array area MCA may be bonded to each other such that the cell wiring structure 160 and the peripheral circuit wiring structure 120 are in contact with each other. In some embodiments, the first bonding pad BP1 and the second bonding pad BP2 may be in contact with each other at the bonding interface BIF. The cell insulating layer 166 and the peripheral circuit insulating layer 126 may be in contact with each other at the bonding interface BIF.

The carrier substrate 210 may then be removed.

The semiconductor device 100 may be completed by performing the foregoing process.

According to some embodiments, the encapsulation line EL including the first metal with excellent oxidation capability may be arranged between the active semiconductor layer AP and the bit line BL. The oxide region PO may be formed in a partial region of the encapsulation line EL. The oxygen vacancy may be generated inside the active semiconductor layer AP while forming the oxide region PO of the encapsulation line EL adjacent interfaces or contact areas therebetween, thereby increasing the on-state current of the cell transistor CTR. In addition, the encapsulation line EL may reduce or prevent diffusion of hydrogen ions from the bit line BL. Thus, the semiconductor device 100 may have excellent reliability.

In some embodiments, described is the case where the word line WL is first formed on the sidewall of the mold line 132, and then the gate insulating layer GI and the active semiconductor layer AP are formed. However, in other embodiments, the active semiconductor layer AP may be first formed on the sidewall of the mold line 132, and then the gate insulating layer GI and the word line WL may be formed. Before the encapsulation line EL is formed, the upper portion of the active semiconductor layer AP may be removed to form a recess. Thus, the encapsulation line EL may be formed with the protrusion ELP filling the inside of the recess. In this case, the semiconductor device 100A described with reference to FIGS. 7 to 10 may be formed.

In some embodiments, described is a method in which a front surface of the carrier substrate 210 is bonded to a front surface of the substrate 110 such that the bit line BL is connected to the peripheral circuit transistor PTR after first forming the cell capacitor CAP on the carrier substrate 210, then forming the cell transistor CTR and the bit line BL on the cell capacitor CAP, and forming the peripheral circuit transistor PTR on the substrate 110. However, in other embodiments, the cell transistor CTR may be first formed on the carrier substrate 210, the cell capacitor CAP may be formed on the cell transistor CTR, and then the bit line BL connected to the cell transistor CTR may be formed after the carrier substrate 210 is removed. After the peripheral circuit transistor PTR is formed on the substrate 110, a rear face of the substrate 110 may be bonded onto a cell substrate such that the bit line BL is connected to the peripheral circuit transistor PTR by a through via passing through the substrate 110.

While the inventive concepts have been particularly shown and described with reference to embodiments thereof, it will be understood that various changes in form and details may be made therein without departing from the scope of the following claims.

What is claimed is:

1. A semiconductor device comprising:
a mold line extending in a first horizontal direction;
an active semiconductor layer on a sidewall of the mold line and comprising a first oxide semiconductor;
a word line on a first sidewall of the active semiconductor layer and extending in the first horizontal direction ;
a cell capacitor on a top surface of the active semiconductor layer;
a bit line on a bottom surface of the active semiconductor layer opposite the top surface and extending in a second horizontal direction that intersects the first horizontal direction; and
an encapsulation line extending in the second horizontal direction between the bottom surface of the active semiconductor layer and the bit line, the encapsulation line comprising a first metal, wherein the first metal comprises at least one of tantalum, niobium, or aluminum.

2. The semiconductor device of claim 1, wherein a portion of the encapsulation line is in direct contact with at least a portion of the active semiconductor layer, and
the encapsulation line comprises an oxide region within the portion of the encapsulation line adjacent to an interface between the portion of the encapsulation line and the at least a portion of the active semiconductor layer.

3. The semiconductor device of claim 2, wherein the oxide region comprises at least one of tantalum oxide, niobium oxide, or aluminum oxide.

4. The semiconductor device of claim 2, wherein the oxide region is in the portion of the encapsulation line that is in direct contact with the bottom surface of the active semiconductor layer.

5. The semiconductor device of claim 4, wherein an entirety of the bottom surface of the active semiconductor layer is on the encapsulation line, and the bottom surface of the active semiconductor layer is free of direct contact with a top surface of the bit line.

6. The semiconductor device of claim 1, further comprising:
a passivation layer on a second sidewall of the active semiconductor layer opposite the first sidewall thereof, wherein a top surface of the passivation layer is closer to the bit line than the top surface of the active semiconductor layer.

7. The semiconductor device of claim 6, wherein the encapsulation line comprises a protrusion that protrudes away from the bit line and toward the top surface of the passivation layer.

8. The semiconductor device of claim 7, wherein a sidewall of the protrusion is in contact with the second sidewall of the active semiconductor layer, and a top surface of the protrusion is in contact with a bottom surface of the passivation layer.

9. The semiconductor device of claim 7, wherein the encapsulation line has a first width in the first horizontal direction, and
the bit line has a second width that is less than the first width in the first horizontal direction.

10. The semiconductor device of claim 7, wherein the protrusion vertically overlaps with the passivation layer in a vertical direction that is perpendicular to the first and second horizontal directions.

11. The semiconductor device of claim 1, wherein the encapsulation line comprises a protrusion that protrudes away from the bit line and toward the bottom surface of the active semiconductor layer.

12. The semiconductor device of claim 11, wherein the protrusion vertically overlaps up to an entirety of the bottom surface of the active semiconductor layer in a vertical direction that is perpendicular to the first and second horizontal directions.

13. The semiconductor device of claim 12, wherein the encapsulation line comprises an oxide region within a portion of the encapsulation line adjacent to an interface between a top surface of the protrusion and the bottom surface of the active semiconductor layer, and the oxide region is in the protrusion.

14. The semiconductor device of claim 12, wherein the protrusion has a first width in the first horizontal direction, and the bit line has a second width that is less than the first width in the first horizontal direction.

15. A semiconductor device comprising:
a mold line extending in a first horizontal direction;
an active semiconductor layer on a sidewall of the mold line and comprising a first oxide semiconductor;
a word line extending along a first sidewall of the active semiconductor layer in the first horizontal direction;
a cell capacitor on a top surface of the active semiconductor layer;
a bit line on a bottom surface of the active semiconductor layer opposite the top surface and extending in a second horizontal direction that intersects the first horizontal direction; and
an encapsulation line extending in the second horizontal direction between the bottom surface of the active semiconductor layer and the bit line, the encapsulation line comprising a first metal, wherein the first metal comprises at least one of tantalum, niobium, or aluminum,
wherein a portion of the encapsulation line is in contact with the bottom surface of the active semiconductor layer, and the portion of the encapsulation line comprises an oxide region comprising at least one of tantalum oxide, niobium oxide, or aluminum oxide.

16. The semiconductor device of claim 15, wherein an entirety of the bottom surface of the active semiconductor layer is on the encapsulation line, and the bottom surface of the active semiconductor layer is free of direct contact with a top surface of the bit line.

17. The semiconductor device of claim 15, further comprising:
a passivation layer on a second sidewall of the active semiconductor layer opposite the first sidewall thereof, and
wherein a top surface of the passivation layer is closer to the bit line than the top surface of the active semiconductor layer, and the encapsulation line comprises a protrusion that protrudes away from the bit line and toward the top surface of the passivation layer.

18. The semiconductor device of claim 15, wherein the encapsulation line comprises a protrusion that protrudes away from the bit line and toward the bottom surface of the active semiconductor layer, and the oxide region is in the protrusion.

19. A semiconductor device comprising:
a peripheral circuit area and a cell array area on the peripheral circuit area,
wherein the cell array area comprises:
a mold line extending in a first horizontal direction;
an active semiconductor layer on a sidewall of the mold line and comprising a first oxide semiconductor;
a word line extending along a first sidewall of the active semiconductor layer in the first horizontal direction;
a cell capacitor on a top surface of the active semiconductor layer;
a bit line on a bottom surface of the active semiconductor layer opposite the top surface and extending in a second horizontal direction that intersects the first horizontal direction; and
an encapsulation line extending in the second horizontal direction between the bottom surface of the active semiconductor layer and the bit line, the encapsulation line comprising a first metal, wherein the first metal comprises at least one of tantalum, niobium, or aluminum.

20. The semiconductor device of claim 19, wherein the bottom surface of the active semiconductor layer is on at least a portion of the encapsulation line,
the at least a portion of the encapsulation line has a first width in the first horizontal direction, and
the bit line has a second width that is less than the first width in the first horizontal direction.
